(19) United States
(12) Patent Application Publication
(10) Pub. No.: US 2025/0155168 A1
(43) Pub. Date: May 15, 2025

(54) SOLID STATE COOLER

(71) Applicant: International Business Machines Corporation, Armonk, NY (US)

(72) Inventors: Bernd W. Gotsmann, Horgen (CH); Federico Balduini, Zurich (CH); Lorenzo Rocchino, Zurich (CH); Bogdan Cezar Zota, Rueschlikon (CH); Heinz Schmid, Dahlienstrasse (CH)

(21) Appl. No.: 18/506,214

(22) Filed: Nov. 10, 2023

(51) Int. Cl. F25B 21/00; H10N 19/00

(52) U.S. Cl. CPC F25B 21/00; H10N 19/00; F25B 2321/002

(57) ABSTRACT

A cooling system comprises a system heat sink and a first magnetocaloric thermal transport medium. The first magnetocaloric thermal transport medium is connected to the system heat sink. The first magnetocaloric thermal transport medium comprises a semimetal.

### BACKGROUND

The present invention relates to cooling systems, and more specifically, to cooling systems for electronic applications.

Cooling systems for electronic applications take different forms based on the properties of the electronic application. Large-scale electronics with low temperature sensitivity, such as server racks, often rely on arrays of fans to move air over the electronics. Such solutions use air that is approximately room temperature to maintain the heat-producing device (e.g., memory, processor) at a temperature below 100 Celsius degrees (i.e., 373.15 Kelvin).

Cooling systems for more temperature-sensitive electronics, however, typically utilize more complex solutions to maintain lower temperatures. Quantum systems, for example, include heat-producing devices that should be kept below 2 Kelvin (2 K) for optimal functionality.

### SUMMARY

Some embodiments of the present disclosure can take the form of a first cooling system. The first cooling system may comprise a magnetocaloric heat sink, a device magnetocaloric switch, and a heat-sink magnetocaloric switch. The device magnetocaloric switch connects a heat-producing device to the magnetocaloric heat sink, and the heat-sink magnetocaloric switch is connected to the system heat sink.

Some embodiments of the present disclosure may take the form of a second cooling system. The second cooling system comprises a magnetocaloric medium, a first set of electromagnets, and a second set of electromagnets. The magnetocaloric medium is connected to a heat-producing device and a system heat sink. The first set of electromagnets is located adjacent to a first region of the magnetocaloric medium. The first region is adjacent to the heat-producing device. The second set of electromagnets is located adjacent to a second region of the magnetocaloric medium. The second region is adjacent to the system heat sink.

Some embodiments of the present disclosure may take the form of a third cooling system. The third cooling system comprises a system heat sink and a first magnetocaloric thermal transport medium. The first magnetocaloric thermal transport medium is connected to the system heat sink. The first magnetocaloric thermal transport medium comprises a semimetal.

Some embodiments of the present disclosure may take the form of a method of cooling a heat-producing device. The method may comprise activating a first set of electromagnets that are adjacent to a magnetocaloric medium. The activating the first set of electromagnets divides the magnetocaloric medium into an activated region and an inactivated region.

### BRIEF DESCRIPTION OF THE DRAWINGS

FIGS. 1A-1J depict a cooling system that comprises a magnetocaloric heat sink and a set of magnetocaloric switches throughout example stages of a cooling process, in accordance with embodiments of the present disclosure.

FIG. 2 depicts a process of using a cooling system that comprises a magnetocaloric heat sink and a set of magnetocaloric switches, in accordance with embodiments of the present disclosure.

FIGS. 3A-3P depict a cooling system that comprises several regions of a magnetocaloric thermal transport medium throughout example stages of a cooling process, in accordance with embodiments of the present disclosure.

FIG. 4 depicts a process of using a cooling system that comprises a set of electromagnets that can be used to pump heat through a magnetocaloric medium, in accordance with embodiments of the present disclosure.

FIG. 5 depicts a magnetocaloric thermal transport medium with a thermal transport supplement applied thereto, according to embodiments of the present disclosure.

FIGS. 6A-6R depict a series of stages of forming a cooling system that comprises a set of electromagnets that can be used to pump heat through a magnetocaloric medium, in accordance with embodiments of the present disclosure.

FIGS. 7A-7L depict a series of stages of forming a cooling system that comprises a magnetocaloric heat sink and a set of magnetocaloric switches, in accordance with embodiments of the present disclosure.

### DETAILED DESCRIPTION

Cooling systems for electronic applications take various forms depending on the needs of those applications. Standard desktop computers, for example, operate a set of fans to move room-temperature air over heat-producing devices within the computers (e.g., system processors, voltage regulation modules, system memory). These systems are typically sufficient to maintain heat-producing devices at temperatures higher than room temperature, but within system specification (e.g., between 50 and 90 Celsius degrees).

Some cooling systems for more sensitive electronic (e.g., quantum devices) applications take more complex forms to maintain heat-producing devices at far lower temperatures. For example, typical quantum-computer cooling systems involve transporting liquid hydrogen or helium instead of room-temperature air. Some cooling systems also take advantage of adiabatic cooling, in which the heat capacity of a substance is manipulated to encourage the substance to remove heat from a heat-producing component at one location and release that heat to the environment at another location.

In some adiabatic systems, a cooling substance is pressurized in a first location, causing the substance to transition from a gaseous to a liquid state. As a result of this compression, the heat capacity of the cooling substance is reduced, causing it to tend to release heat to the surrounding environment. Upon releasing heat to the surrounding environment, the cooling substance is then relocated and depressurized, causing it to transition from a liquid back to a gaseous state. This transition causes the internal energy of the cooling substance to decreased, increasing the heat capacity of the cooling substance. This, in turn, causes it to tend to accept to heat from the surrounding environment. If the cooling substance is caused to contact a heat-producing device in this gaseous state, the cooling substance may remove heat from the heat-producing device. That heat can then be transported away from the heat-producing device with the cooling substance, which can then be transitioned back to a gaseous state again to release the heat to the environment. Some cryocoolers, for example, cool very low-temperature electronics by transitioning nitrogen, hydrogen, or helium through the above-described process. These systems can maintain temperatures at heat-producing devices below 2 Kelvin.

Rather than rely on transitioning a cooling substance between gaseous and liquid states, some cryocoolers utilize magnetocaloric properties of a cooling substance to create an adiabatic effect. Substances with magnetocaloric properties (sometimes referred to herein as “magnetocaloric substances”) can be exposed to a magnetic field in order to increase their heat capacity, then isolated from that magnetic field to reduce their heat capacity. For example, some fluids containing magnetocaloric substances can be pumped through an area that contains a magnetic field, increasing their heat capacity. The fluid can then be pumped to contact a heat-producing device, causing the fluid to accept heat from the heat-producing device. The fluid can then be pumped away from the heat-producing device and out of the magnetic field, causing the heat capacity of the magnetocaloric substance to decrease. The fluid, as a result, transfers the heat that was accepted from the heat-producing element to the surrounding environment.

In some cooling solutions, solid magnetocaloric substances can be utilized rather than fluids containing magnetocaloric substances. In these solutions, the solid magnetocaloric substance is typically moved such that it contacts a heat-producing device within a magnetic field. The magnetic field causes the heat capacity of the magnetocaloric substance to increase, and thus the substance accepts heat from the heat-producing device. The magnetocaloric substance can then be moved away from the heat-producing device and out of the magnetic field using a mechanical process, such as with a piston. Once moved outside of the magnetic field, the magnetocaloric substance can be placed in contact with a heat sink, causing the substance to transfer heat to the heat sink.

The adiabatic cooling solutions discussed above all require some type of mechanical intervention in the solution. For example, transporting fluids (gas or liquid) typically requires a pump, and moving a solid magnetocaloric component may require a piston or a lever. Because of the inclusion of this mechanical intervention, these solutions are difficult to scale to small sizes. The mechanical systems required for these cryocooling solutions involve very small moving parts that are prone to fatigue and failure. Thus, even if it is possible to operate the parts at such small sizes, doing so sometimes requires a significant investment in maintenance.

This is unfortunate, because many heat-producing devices that may benefit most from temperatures at or below 2 Kelvin are very small. For example, a cooling of the types discussed above that would be capable of providing sufficient cooling for a detector pixel, a quantum device, or a logic component would typically be orders of magnitude larger than the pixel, device, or component.

The size requirements of cooling these devices to single-digit temperatures often acts as a prohibitive barrier of using these devices beyond academic settings. For example, the costs of the materials required for building a cryocooling apparatus for a single quantum device could make the device not worth investing in.

The barriers to entry that is created by current cryocooling solutions can act to prevent investment into temperature-sensitive devices such as quantum devices. This in turn slows progress in developing fields like quantum technology. Until these issues are addressed, operating temperature-sensitive devices is likely to be limited to academic and niche business settings, preventing much of society from benefitting from the potential advantages that these devices could provide.

One potential solution to the above issues is to utilize a solid-state magnetocaloric cooler with no moving parts. For example, a heat-producing device, such as a quantum sensor, could be connected to a sample of magnetocaloric material, which could in turn be connected to a heat sink. In theory, by exposing the sample of magnetocaloric material to a magnetic field, the heat capacity of the sample could be made to increase, causing it to accept heat from the heat-producing device. Further, and again in theory, by the isolating the sample of magnetocaloric material from the magnetic field, the heat capacity of the sample could be made to decrease, causing it to transfer heat to the heat sink.

Unfortunately, operating such a solid-state magnetocaloric cooler also has several challenges. To begin, the magnetocaloric effect in most materials is very small. In other words, the increase in heat capacity and thermal conductivity in most materials is very small when those materials are exposed to even a very strong magnetic field. As a result, the ability of these systems to cool is very limited, and not suitable for temperature-sensitive electronics. In other words, in order to provide enough difference in heat capacity, a system may need to be built with a very large sample of magnetocaloric material that requires a very powerful magnetic field. Such a cooling system would be expensive to build, expensive to run, and may still only provide enough cooling to allow only temporary operation of a temperature-sensitive device.

Further, such a solid-state magnetocaloric cooler may, as explained, require a powerful magnetic field. Unfortunately, this magnetic field would likely not only interact with the magnetocaloric sample, but may also interfere with the operation of the heat-producing device that the system is attempting to cool. For example, quantum devices, in addition to being very temperature sensitive, are typically also very sensitive to magnetic fields. Thus, the strength of the magnetic field required for some designs of magnetocaloric coolers makes them unsuitable for the use cases for which they have been developed.

To address the issues identified above, some embodiments of the present disclosure utilize magnetocaloric coolers with lower-strength magnetic fields and magnetocaloric thermal transport media that provide high cooling performance. There are several innovative features by which the embodiments of the present disclosure accomplish these advantages.

To begin, some embodiments of the present disclosure utilize thermal transport media (i.e., one or more solid media that are designed to transport heat from heat-producing device to a heat sink) that are composed of semimetals. For example, topological semimetals with a small Fermi surface, high electron mobility, and large screening length may exhibit a large magnetocaloric effect even when a relatively small, localized magnetic field is applied to the semimetal. Thus, by utilizing a thermal transport medium composed of, for example, crystalline tantalum arsenide (TaAs), crystalline zirconium pentatelluride (ZrTe5), or crystalline niobium phosphide (NbP), sufficient magnetocaloric effect can be achieved to promote significant heat transfer from a heat-producing device without exposing that heat-producing device to significant magnetic flux.

Some embodiments of the present disclosure also utilize multiple localized magnetic fields to create magnetocaloric effect in thermal transport media rather than a single large magnetic field. This may be performed, for example, by utilizing a set or series of small electromagnets to produce localized magnetic fields. As will be discussed in more detail below, these electromagnets may take the form of a solenoid, a patterned wire, a flat patterned coil, or others.

For example, some embodiments of the present disclosure may incorporate a thermal transport medium that take the form of an intermediate magnetocaloric heat sink (sometimes referred to herein simply as a “magnetocaloric heat sink”). The intermediate magnetocaloric heat sink is referred to herein as an “intermediate” magnetocaloric heat sink because it is a magnetocaloric component of a cooling system that is designed to act as a heat sink between a heat-producing device and a system heat sink operated in a heat pump cycle. The intermediate magnetocaloric heat sink may be connected to a heat-producing device through a long and thin magnetocaloric component. This long and thin magnetocaloric component, as will be explained herein, can be operated as a steady-state thermal switch that can switch a transfer of heat between other components on and off. This component will thus be referred to herein as a “magnetocaloric switch.”

The magnetocaloric switch may be significantly longer in the dimension between the heat-producing device and the intermediate magnetocaloric heat sink than it is think in other dimensions. This may not only enable a relatively weak magnetic field to produce a significant magnetocaloric effect in the magnetocaloric switch, but may also cause the overall heat capacity of the magnetocaloric switch to remain relatively small. In other words, exposing the magnetocaloric switch to a magnetic field increases its thermal conductance, enabling heat to pass through the magnetocaloric switch. However, exposing the magnetocaloric switch to the magnetic field, due to the dimensions of the switch, does not result in the switch being able to hold a significantly high amount of heat.

For this reason, independent electromagnets may be placed in close proximity (e.g., within a millimeter) of the intermediate magnetocaloric heat sink and magnetocaloric switch. Activation of the electromagnet that is in proximity to the intermediate magnetocaloric heat sink may expose the intermediate magnetocaloric heat sink to a magnetic field that increases the heat capacity of the intermediate magnetocaloric heat sink. Thus, when both electromagnets for the magnetocaloric switch and intermediate magnetocaloric heat sink are activated, heat can flow from the heat-producing device, through the magnetocaloric switch, and into the intermediate magnetocaloric heat sink. Further, if the electromagnet that is located adjacent to the magnetocaloric switch is then deactivated, the thermal conductance of the magnetocaloric switch decreases, preventing heat from returning from the intermediate magnetocaloric heat sink back to the heat-producing device.

Because the electromagnets for the magnetocaloric heat sink and the magnetocaloric switch can be operated independently, each electromagnet can be designed to be smaller. This may negate the effects of either electromagnet on the heat-producing device. Further, because the electromagnet that is adjacent to the magnetocaloric switch may be particularly small, the effect of that electromagnet on the heat-producing device may be even more limited. Finally, because the electromagnet that is adjacent to the magnetocaloric heat sink may be separated from the heat-producing device by the magnetocaloric switch, the effect of that electromagnet on the heat-producing device may also be even more limited.

Finally, once the heat from the heat-producing device is effectively trapped in the magnetocaloric heat sink, it can be transferred to a system heat sink by isolating the magnetocaloric heat sink from the magnetic field. This would reduce the heat capacity of the magnetocaloric heat sink, causing the heat from the magnetocaloric heat sink to pass to the system heat sink. In some embodiments, the magnetocaloric heat sink may be directly connected to the system heat sink, allowing direct transfer of heat. In other embodiments, the magnetocaloric heat sink may be indirectly connected to the system heat sink. For example, a second magnetocaloric switch may connect the magnetocaloric heat sink to the system heat sink. This second magnetocaloric switch may be activated by a third electromagnet. This activation, similar to the activation of the first magnetocaloric switch, may enable heat to pass through the second magnetocaloric switch from the magnetocaloric heat sink to the system heat sink without significantly increasing the heat capacity of the second magnetocaloric switch. Further, once the heat has been transferred to the magnetocaloric heat sink, the second magnetocaloric switch could be isolated from the magnetic field, effectively preventing the heat in the system heat sink from returning to the magnetocaloric heat sink.

Of note, some embodiments of the above-discussed design may utilize topological semimetals for the magnetocaloric heat sink and magnetocaloric switches. In some such embodiments, all magnetocaloric materials may be composed of the same semimetals, whereas in other embodiments different components may be composed of different semimetals. For example, in some embodiments the magnetocaloric heat sink, first magnetocaloric switch, and second magnetocaloric switch may all be composed of NbP. In other embodiments, the magnetocaloric heat sink may be composed of NbP, whereas the magnetocaloric switches may be composed of TaAs.

Some embodiments of the present disclosure also utilize multiple localized magnetic fields to operate a magnetocaloric thermal transport medium as a form of heat pump. For example, a thermal transport medium may take the form of a magnetocaloric substance that connects to a heat-producing device and a system heat sink. The thermal transport medium may adjacent to a set of electromagnets that are independently addressable and that span the distance between the heat-producing device and the system heat sink. As a result, these electromagnets effectively divide the magnetocaloric thermal transport medium into a set of regions that may be exposed to an electric field independently of other regions of the thermal transport medium. In other words, the thermal conductance and heat capacity one or more regions of the thermal transport medium could be altered with the electromagnets without altering the thermal conductances and heat capacities of other regions of the thermal transport medium.

This allows the magnetocaloric thermal transport medium to act as a heat pump without the mechanical intervention that would normally be required a heat pump functionality. For example, the electromagnet that is located adjacent to the region of the thermal transport medium that is closest to the heat-producing device could be activated. This would increase the thermal conductance and heat capacity of that region of the thermal transport medium, allowing heat to transfer from the heat-producing device to the thermal transport medium. The electromagnet adjacent to the next region of the thermal transport medium could then be activated, allowing heat to transfer from the first region to the second region. The electromagnet adjacent to the first region could then also be deactivated, which would encourage the remaining heat from the first region to be transferred to the second region. This pattern could be repeated throughout all regions of the thermal transport medium until the heat was pumped all the way to the system heat sink. As a result, magnetocaloric thermal transport media that follow this mode of operation may be referred to herein as magnetocaloric heat pumps.

In some embodiments, the magnetocaloric heat pump may be composed of a topological semimetal. As discussed above, forming the magnetocaloric heat pump from a topological semimetal may significantly increase the thermal transport material's magnetocaloric response to the changing magnetic field. This may, in some embodiments, increase the performance of the heat pump.

Of note, portions of this disclosure sometimes reference a component being connected to another component. Unless otherwise indicated, connecting to another component should be interpreted herein as either being directly connecting to that component or being indirectly connected to that component. As discussed herein, when a first component is directly connected to a second component, those two components are physically contacting each other or contacting with only a negligible separation between them. For example, a heat-producing component may be said to be directly connected to a heat sink even if a microscopic layer of air exists between most of the surface area of that connection. Similarly, two conductive contacts may be described as being directly connected to each other if the only thing between them is a negligibly thin layer to promote their adhesion to each other if that layer does not in any other way affect their interaction.

On the other hand, when a first component is indirectly connected a second component, those two components may be connected only through the physical contacts of intervening components. For example, a heat-producing component may be described as indirectly connected to a system heat sink if the heat-producing component is directly connected to a magnetocaloric switch that is directly connected to an intermediate magnetocaloric heat sink that is then directly connected to a second magnetocaloric switch that is then directly connected to the system heat sink.

For added clarity, the connections between multiple components of the embodiments of this disclosure may be described in relation to each other. One example of this may describe a first component as proximately connected to a second component with respect to (i.e., compared to) a third component. Recalling the previous example for illustration, a heat-producing component may be directly connected to a magnetocaloric switch that is directly connected to an intermediate magnetocaloric heat sink, that is directly connected to a second magnetocaloric switch. In this example, both the intermediate magnetocaloric heat sink and the second magnetocaloric switch are said to be indirectly connected to the heat-producing component. Further, the intermediate magnetocaloric heat sink would be described as proximately connected to the heat-producing component with respect to the second heat-producing component because the intermediate magnetocaloric heat sink is more closely connected to the heat-producing component than the second magnetocaloric switch is connected to the heat-producing component.

Finally, the discussions of embodiments of the present disclosure may utilize the terms thermal conductivity, thermal conductance, and heat capacity. As used herein, thermal conductivity refers to the ability of heat to radiate through the material (e.g., the connected molecules) of a component, whereas thermal conductance refers to the ability of heat to radiate through a component. For this reason, the term “thermal conductivity” should be interpreted as referring to the properties of a material itself, whereas thermal conductance should be interpreted as describing an aggregate property of the component. For example, the thermal conductance of a niobium phosphide magnetocaloric switch depends not only on the present conductivity of the niobium phosphide in the switch, but also the shape of the switch.

More specifically, the niobium phosphide within a long and skinny magnetocaloric switch would have the same thermal conductivity as the niobium phosphide within a short and broad magnetocaloric switch in the same environmental conditions (e.g., temperature and exposure to magnetic flux). However, the long and skinny magnetocaloric switch would have a lower thermal conductance than the short and broad magnetocaloric switch due to its long and skinny shape. Further, because the thermal conductance of a component is based on the thermal conductivity of the materials within that component, the thermal conductance of both magnetocaloric switches could be adjusted by exposing the niobium phosphide within those switches to a magnetic field.

Finally, “heat capacity” as referred to herein, can refer to the heat capacity of a component or the specific heat capacity of a material in that component. The heat capacity of a component refers to the amount of heat energy that that component can hold in a set of environmental conditions. The specific heat capacity of a material can be interpreted as the ability of the molecules of that material to hold heat energy irrespective of the shape of the component that those molecules form.

For the purpose of this disclosure, the heat capacity of a component can be interpreted as a factor of a component's mass and the specific heat capacity of the material within that component. For example, the specific heat capacity of niobium phosphide may be relatively high when exposed to a magnetic field, but relatively low when isolated from a magnetic field. However, a component with a large mass (e.g., a magnetocaloric heat sink) may have a much larger heat capacity than a component with a small mass (e.g., a magnetocaloric switch) even if the specific heat capacity of the material within those components (e.g., niobium phosphide) is identical. Further, because the heat capacity of a component is a factor of the specific heat capacity of the material within that component, the heat capacity of a component can be adjusted by affecting the specific heat capacity of that component's material. It is for this reason that the heat capacity of a magnetocaloric heat sink may be adjusted by exposing the niobium phosphide within that magnetocaloric heat sink to a magnetic field.

The above discussions of the embodiments of the present disclosure and the advantages thereof can be better understood by reviewing the figures of the present disclosure.

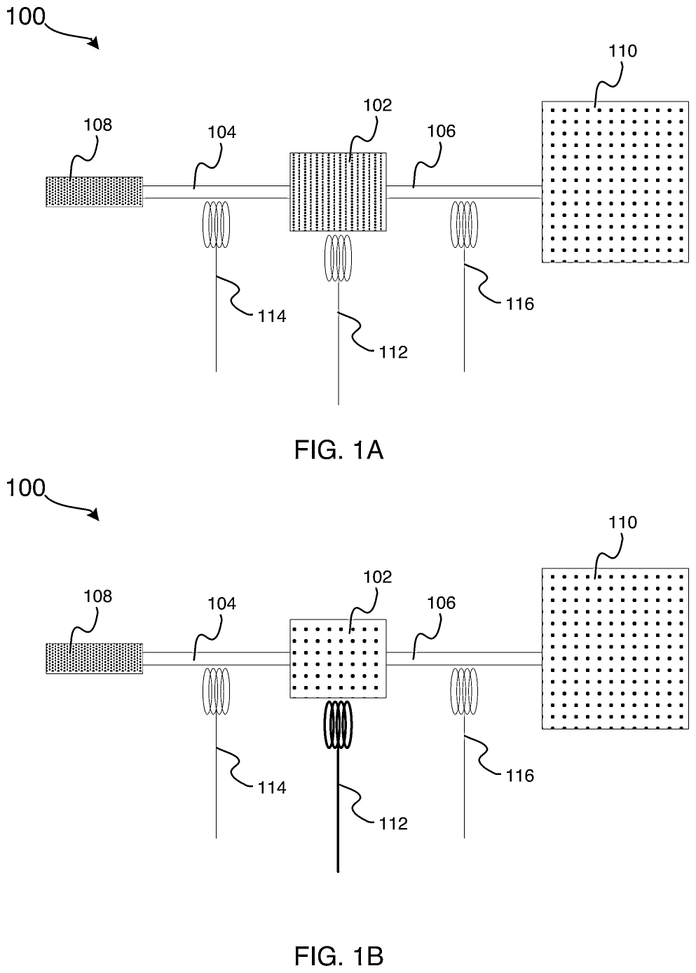

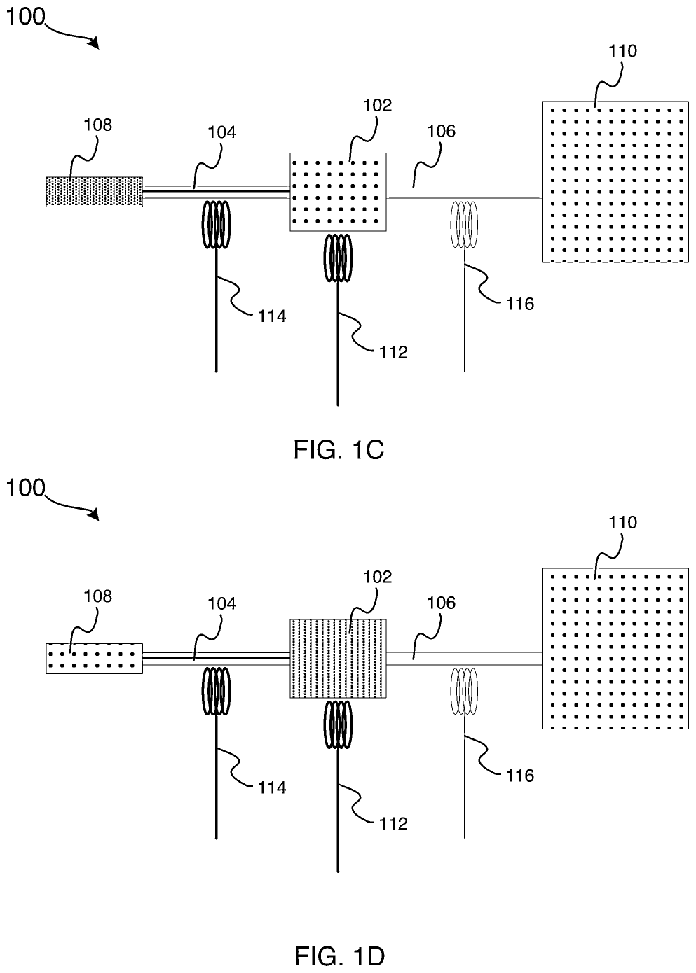

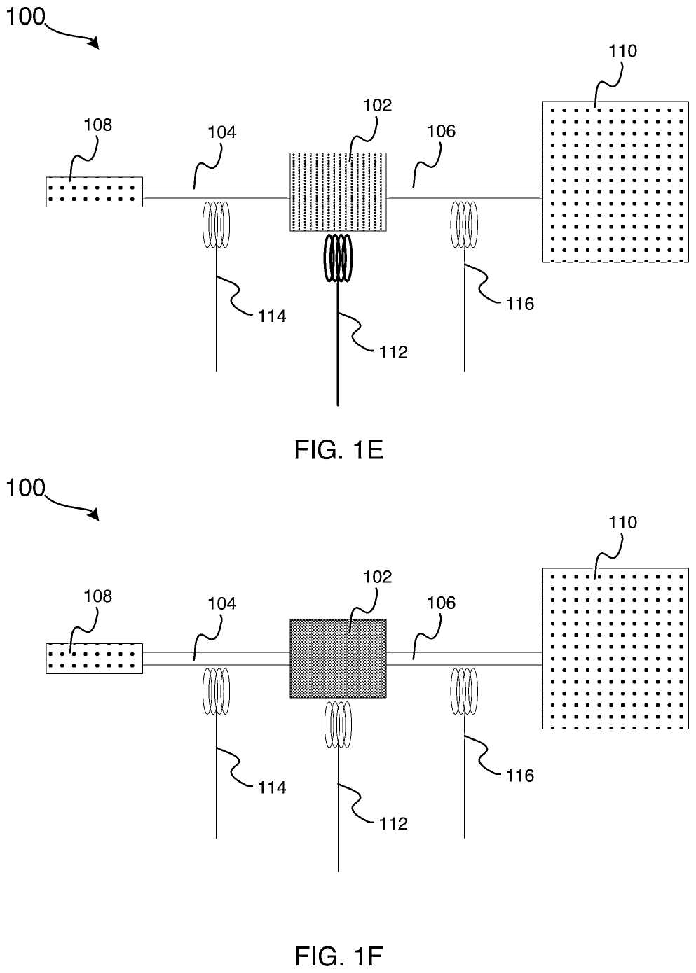

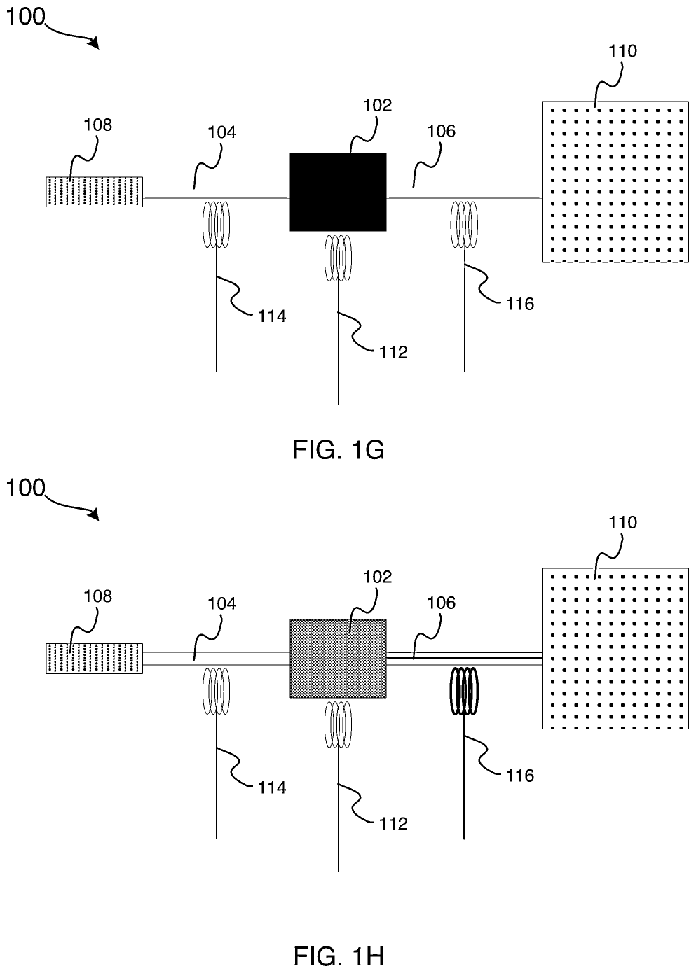

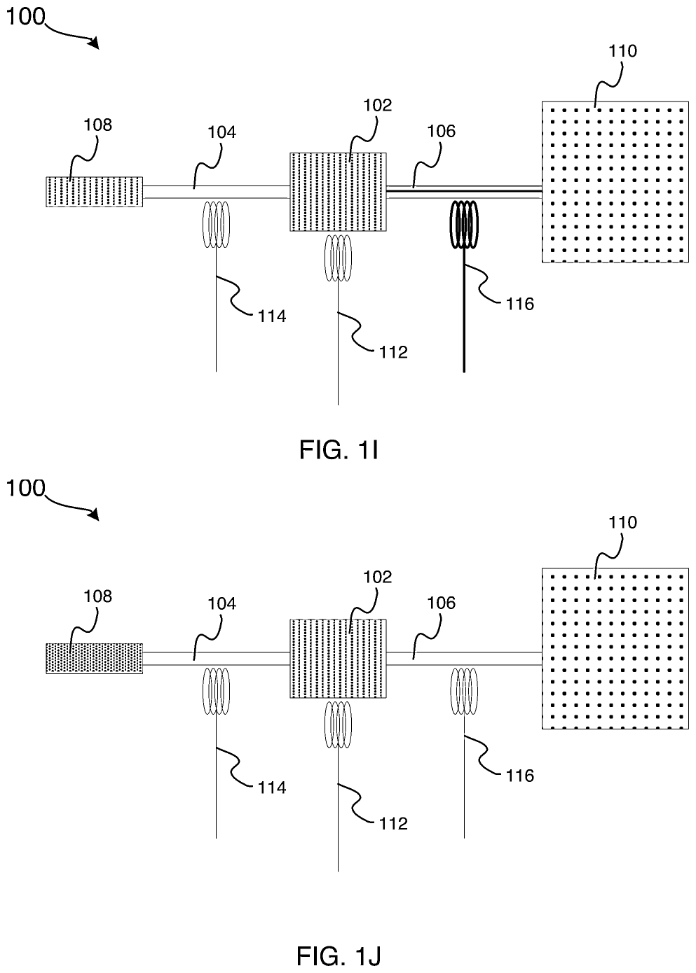

For example, FIGS. 1A-1J depict a cooling system 100 that comprises a magnetocaloric heat sink 102 and a set of magnetocaloric switches 104 and 106 throughout example stages of a cooling process, in accordance with embodiments of the present disclosure. Of note, FIGS. 1A-1J are intended to only provide an abstracted representation of a cooling system for the purpose of understanding.

Magnetocaloric heat sink 102 and magnetocaloric switches 104 and 106 serve to thermally connect heat-producing device 108 to system heat sink 110. For this reason, magnetocaloric heat sink 102 and magnetocaloric switches 104 and 106 may be referred to collectively as the thermal transport media of cooling system 100. Because magnetocaloric switch 104 is directly connected to heat-producing device 108, it may be referred to herein as a “device magnetocaloric switch.” Similarly, because magnetocaloric switch 106 is directly connected to system heat sink 110, it may be referred to as a “heat sink magnetocaloric switch.”

Heat-producing device 108 may take the form of, for example, a quantum sensor or other quantum device, a detector pixel, a logic device (e.g., on a processor chip), or a device used for infrared imaging, metrology, or precision chemistry. System heat sink 110 may take the form of, for example, a large mass of conductive material, a series of fins, or a thermal bath.

Cooling system 100 also depicts electromagnets 112, 114, and 116. Electromagnet 112 has been placed adjacent to magnetocaloric heat sink 102, electromagnet 114 has been placed adjacent to magnetocaloric switch 104, and electromagnet 116 has been placed adjacent to magnetocaloric switch 106. Each of electromagnets 112-116 are independently addressable, meaning each could be activated individually without activating the others. Further, the magnetic fields created by each of electromagnets 112-116 is of a strength that creates a magnetocaloric effect on the thermal transport medium to which the electromagnet is adjacent, but that does not create a strong magnetocaloric effect on the thermal transport media to which it is not adjacent.

For this reason, as used in the purpose of this disclosure, an electromagnet being “adjacent to” a thermal transport medium should be interpreted as being placed close enough to that thermal transport medium to create a significant magnetocaloric effect on that thermal transport medium when the electromagnet is activated (i.e., when the electromagnet exposes the thermal transport medium to a magnetic field). This distance may range, for example between a few nanometers in use cases in which a microcoil is integrated with, or wrapped around, a magnetocaloric switch and a few centimeters in larger coolers with larger solenoids. A magnetocaloric effect may be considered “significant” based on the circumstance of the use case, when it results in, for example, a 300% increase in thermal conductivity (e.g., from 5 W/mK to 20 W/mK) or 700% increase in specific heat capacity (e.g., from 0.005 j/cm³ K to 0.04 j/cm³ K).

Similarly, an electromagnet being “not adjacent to” a thermal transport medium should be interested as not being placed close enough to that thermal transport medium to create a significant magnetocaloric effect on that thermal transport medium when the electromagnet is activated.

Electromagnets 112-116 are depicted as simple coils for the sake of understanding, but could take various forms depending on the use case in which cooling system 100 is integrated. For example, electromagnets 112-115 could take the form of solenoids that are placed near their respective components, solenoids that are wrapped around their respective components (e.g., the coils of electromagnet 114 could be wrapped around magnetocaloric switch 104), patterned wires, or flat patterned coils. In some embodiments, each of electromagnets 112-116 could actually represent several electromagnets that may be activated together in order to expose their corresponding component to electromagnetic flux.

Magnetocaloric heat sink 102 and magnetocaloric switches 104 and 106 are composed of a magnetocaloric material such as a topological semimetal. Thus, when any of electromagnets 112-116 are activated, the associated thermal transport medium will be exposed to a magnetic field and the thermal conductance and heat capacity of the thermal transport medium will increase. For example, if electromagnet 114 is activated, magnetocaloric switch 104 will be exposed to a magnetic field, causing the thermal conductance and heat capacity of magnetocaloric switch 104 to increase.

In some embodiments, magnetocaloric heat sink 102 and magnetocaloric switches 104 and 106 may be composed of the same magnetocaloric material. For example, all three may be composed of niobium phosphide. In other embodiments, different materials may be used to create the different thermal transport media. For example, in some embodiments magnetocaloric heat sink 102 may be composed of niobium phosphide, magnetocaloric switch 104 may be composed of tantalum arsenide, and magnetocaloric switch 106 may be composed of zirconium pentatelluride.

While FIGS. 1A-1J are intended as an abstract presentation, the approximate relative dimensions of the components are illustrative of the advantages of the design of cooling system 100. For example, magnetocaloric heat sink 102 is depicted as larger and more massive than magnetocaloric switches 104 and 106, which are depicted as long and narrow. The long and narrow shape of switches 104 and 106 may reduce the overall heat capacity and thermal conductance of the components. For this reason, even if, for example, magnetocaloric switch 104 and magnetocaloric heat sink 102 were made of the same material with the same thermal conductivity and specific heat capacity, magnetocaloric heat sink 102 would still have a greater thermal conductance and heat capacity than magnetocaloric switch 104.

Due to the properties of cooling system 100 described above, cooling system 100 can be utilized as a solid-state cooling system that addresses many of the issues discussed earlier in this disclosure. For example, as illustrated in FIG. 1A, none of electromagnets 112-116 have been activated, which is illustrated in FIG. 1A by the fact that none of electromagnets 112-116 are depicted in thick, bold ink. Thus, none of magnetocaloric heat sink 102 and magnetocaloric switches 104 and 106 are exposed to a magnetic field.

Further in FIG. 1A, heat-producing device 108, due to being in operation, is increasing in temperature. This is illustrated by the density of dots that fill the shape of heat-producing device 108. Similarly, because it is not being exposed to a magnetic field, magnetocaloric heat sink 102 is not undergoing a magnetocaloric effect, and thus the heat conductance and heat capacity of magnetocaloric heat sink 102 is not in a heightened state. For this reason, magnetocaloric heat sink 102 is not accepting heat from its surrounding environment in FIG. 1A.

However, in FIG. 1B, electromagnet 112 has been activated, exposing magnetocaloric heat sink 102 to a magnetic field. The magnetic field has created a magnetocaloric effect in heat sink 102, increasing its heat capacity and thermal conductance. Magnetocaloric sink 102 is therefore in a condition to accept heat from its surrounding environment. This is illustrated in FIG. 1B by the density of dots that fill the shape of magnetocaloric heat sink 102 decreasing from FIGS. 1A to 1B.

In FIG. 1B, electromagnet 114 has not been activated. Thus, magnetocaloric switch 104 has not been exposed to a magnetic field, and thus its conductance has not been increased. For this reason, the heat that is being produced by heat-producing device 108 in FIG. 1B cannot spread to magnetocaloric heat sink 102, even though magnetocaloric heat sink 102 is in a condition to accept heat from heat-producing device 108.

In FIG. 1C, both electromagnets 112 and 114 are activated, exposing both magnetocaloric heat sink 102 and magnetocaloric switch 104 to a magnetic field. This has increased the heat conductance of magnetocaloric switch 104, allowing heat to spread from heat-producing device 108 to magnetocaloric heat sink 102 through magnetocaloric switch 104. This spread is illustrated by the horizontal lines that fill the shape of magnetocaloric switch 104.

This spread of heat is further illustrated in FIG. 1D, in which heat-producing device 108 has cooled as a result of the amount of heat that has spread from heat-producing device 108 to magnetocaloric heat sink 102. This is illustrated by the low density of dots that fill heat-producing device 108 and the increased density of dots that that fill magnetocaloric heat sink 102.

In FIG. 1E, electromagnet 114 has been deactivated. This has decreased the thermal conductance of magnetocaloric switch 104, preventing heat from spreading between heat-producing device 108 and magnetocaloric heat sink 102 in either direction. In other words, the heat that was transferred from heat-producing device 108 to magnetocaloric heat sink 102 is now effectively trapped in magnetocaloric heat sink 102.

In FIG. 1F, electromagnet 112 has also been deactivated. This results in a decrease in the heat capacity of magnetocaloric heat sink 102 back to its original level that was illustrated in FIG. 1A. This results in excess heat energy being contained in magnetocaloric heat sink 102, putting magnetocaloric heat sink 102 in a condition to transfer heat to its surrounding environment. Effectively, magnetocaloric heat sink 102 heats up. The beginning of this process is illustrated in FIG. 1F by the increased density of the dots that fill magnetocaloric heat sink 102.

In FIG. 1G, magnetocaloric heat sink 102 has continued to heat up as a response to the excess heat energy within it. This is illustrated by magnetocaloric heat sink 102 being illustrated as completely black. Of note, continued activity of heat-producing device 108 has caused the temperature of heat-producing device 108 to begin to increase, illustrated in FIG. 1G as a slight decrease in the density of dots that fill heat-producing device 108.

In FIG. 1H, electromagnet 116 has been activated. This exposes magnetocaloric switch 106 to a magnetic field, increasing its thermal conductance. This allows heat to spread from magnetocaloric heat sink 102 to system heat sink 110. Because magnetocaloric heat sink 102 contains excess heat energy, it begins transferring heat energy to system heat sink 110. This is illustrated in FIG. 1H by the slight decrease in the density of the dots that fill magnetocaloric heat sink 102 and the horizontal lines in magnetocaloric switch 106. In typical embodiments, system heat sink 110 will have an effective thermal mass that is significantly larger than the remainder of cooling system 100. As a result, no significant change in the overall heat energy within system heat sink 110 is illustrated in FIG. 1H.

In FIG. 1I, magnetocaloric heat sink 102 has transferred enough heat to system heat sink 110 to return to its original heat energy level that was depicted in FIG. 1A. This may occur, for example, when the temperatures of magnetocaloric heat sink 102 and system heat sink 110 have equalized. In some embodiments, cooling system 100 may be able to detect the temperature of 102, and may recognize it as returned to its original state even if the temperatures of magnetocaloric heat sink 102 and system heat sink 110 have not equalized.

In FIG. 1J, electromagnet 116 has been deactivated, causing magnetocaloric switch 106 to be isolated from magnetic fields. Further, continued activity of heat-producing device 108 has caused the temperature of heat-producing device 108 to further increase, illustrated in FIG. 1J as an increase in the density of the dots that fill heat-producing device 108. As such, FIG. 1J illustrates a return of cooling system 100 to the state in which it was illustrated in FIG. 1A. As such, cooling system 100 can now be operated again through the same stages illustrated in FIGS. 1B through 1I.

Of note, cooling system 100 is depicted as containing a single magnetocaloric heat sink and two magnetocaloric switches. However, in some embodiments not illustrated, additional magnetocaloric heat sinks could be used in series or in parallel. For example, magnetocaloric heat sink 102 could be directly connected, rather to magnetocaloric switch 106, to a third magnetocaloric switch. That third magnetocaloric switch could be directly connected to a second magnetocaloric heat sink, which could in turn be directly connected to magnetocaloric switch 106. Thus, system heat sink 110 would still be indirectly connected to magnetocaloric heat sink 102. However, rather than being indirectly connected to magnetocaloric heat sink 102 through solely magnetocaloric switch 106 (as illustrated in FIGS. 1A-1J), system heat sink 110 would be indirectly connected to magnetocaloric heat sink 102 through the third magnetocaloric switch, the second magnetocaloric heat sink, and magnetocaloric switch 106.

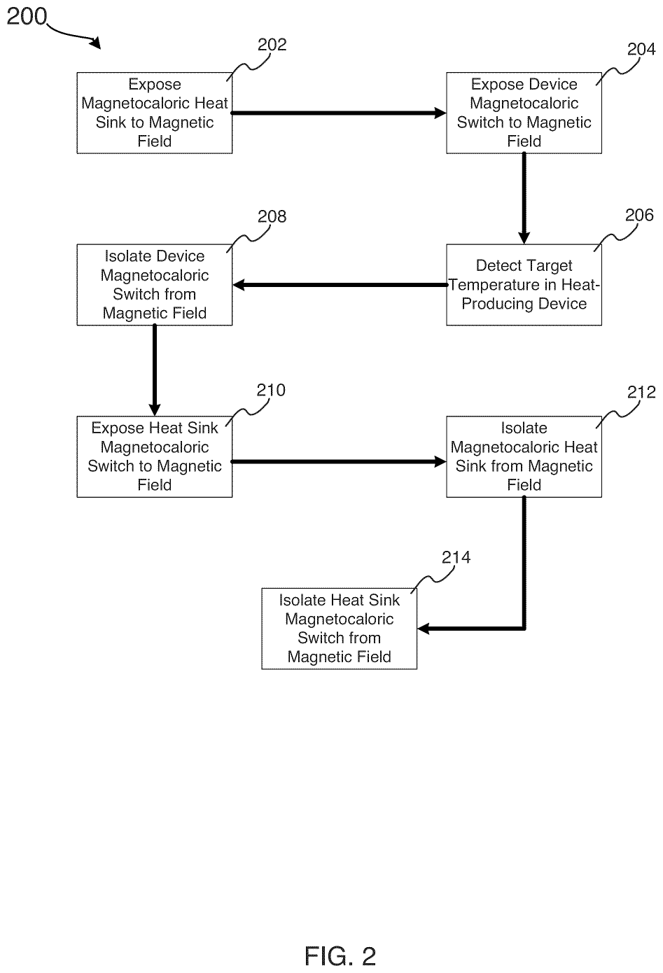

For the sake of understanding, FIG. 2 illustrates an example process of using a cooling system that comprises a magnetocaloric heat sink and a set of magnetocaloric switches similar to cooling system 100. Method 200 begins in block 202, in which an magnetocaloric heat sink is exposed to a magnetic field. This could resemble the stage in which cooling system 100 is presented in FIG. 1B. Block 202 may have been performed, for example, if a cooling system (or a computer operating the cooling system) detected that a heat-producing device that the cooling system is intended to cool reached a threshold temperature. In some use cases, method 200 may be configured to be performed periodically (e.g., as part of a continuous cooling loop), in which case block 202 may have been performed irrespective of a temperature measurement.

Method 200 continues in block 204, in which a device magnetocaloric switch is exposed to a magnetic field. A device magnetocaloric switch may be, as discussed above with respect to FIGS. 1A-1J, a magnetocaloric switch that is directly connected to a heat-producing device. Thus, block 204 may resemble FIG. 1C, in which heat is allowed to transfer from a heat-producing device through a magnetocaloric switch to a magnetocaloric heat sink.

Method 200 continues in block 206, in which a target temperature in the heat-producing device is detected. Typically this block would take the form of detecting that the heat-producing device had cooled to a sufficiently low temperature. After this detection, method 200 proceeds to block 208 in which the device magnetocaloric switch is isolated from the magnetic field. This prevents heat from being transferred between the heat-producing device and the magnetocaloric heat sink. Block 208 may resemble FIG. 1E. Of note, in some embodiments of the present disclosure, the temperature detection of block 206 may be omitted, in which case the method would proceed to isolate the magnetocaloric switch in block 208 after a different triggering event. For example, in some embodiments, method 200 could be configured to proceed from block 204 to block 206 after a pre-determined amount of time.

Method 200 continues in block 210 in which a heat sink magnetocaloric switch is exposed to a magnetic field. A heat sink magnetocaloric switch, as described in relation to FIGS. 1A-1J, is a switch that directly connects to a system heat sink. Thus, block 210 would enable heat between the magnetocaloric heat sink and the system heat sink. Block 210 may resemble activating electromagnet 116 of cooling system 100.

Method 200 continues in block 212 in which the magnetocaloric heat sink is isolated from the magnetic field. This may significantly decrease the heat capacity of the magnetocaloric heat sink, causing it to tend to expel heat into its surrounding environment (e.g., to the system heat sink through the heat sink magnetocaloric switch).

Of note, FIG. 1H above did not illustrate this occurring until after the magnetocaloric heat sink (i.e., magnetocaloric heat sink 102) was isolated from the electric field (i.e., after deactivation of electromagnet 112). However, some implementations of method 200 and of cooling system 100 may isolate the magnetocaloric heat sink after the exposure of the device magnetocaloric switch. Similarly, some embodiments of method 200 may involve isolating the magnetocaloric heat sink before exposure of the device magnetocaloric switch (i.e., performing block 212 before block 210).

Method 200 continues in block 214 in which the heat sink magnetocaloric switch is isolated from the magnetic field. This may be performed, for example, after detecting that the magnetocaloric heat sink has cooled to a target temperature, or a set time period after the heat sink magnetocaloric switch was exposed to the magnetic field. Block 214 may cause the cooling system to resemble cooling system 100 in FIGS. 1A and 1J, and may conclude method 200. Of note, method 200 could be performed on a loop, periodically, or whenever a target temperature of a heat-producing device is detected.

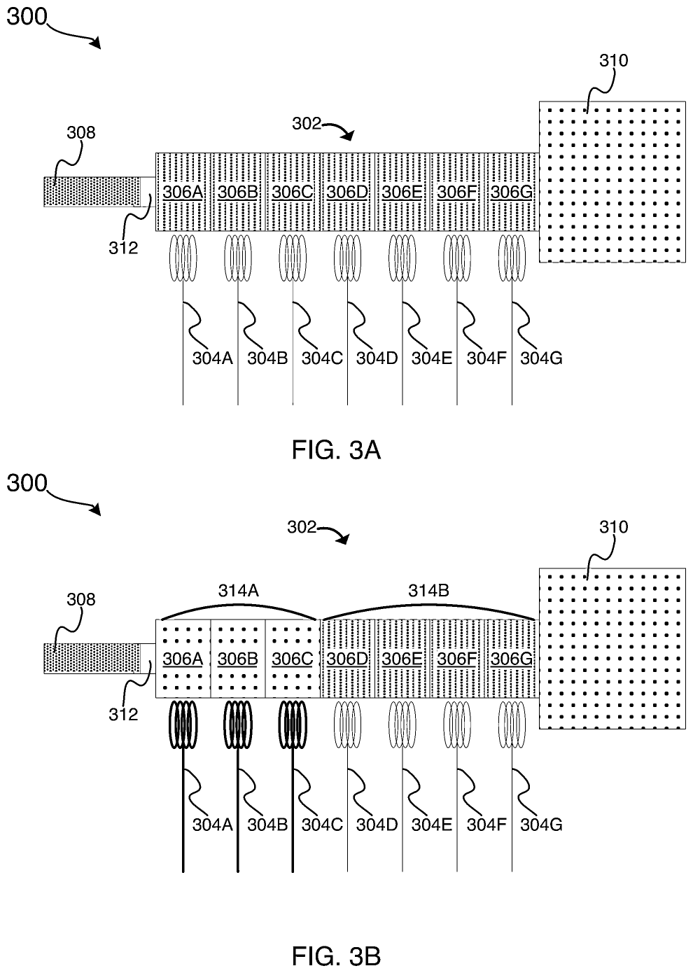

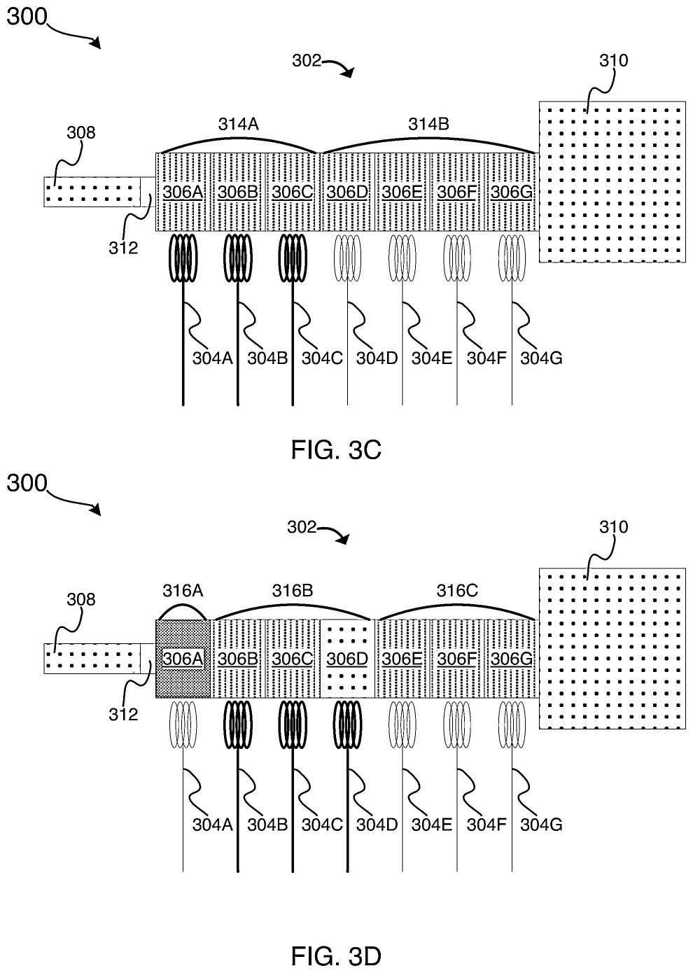

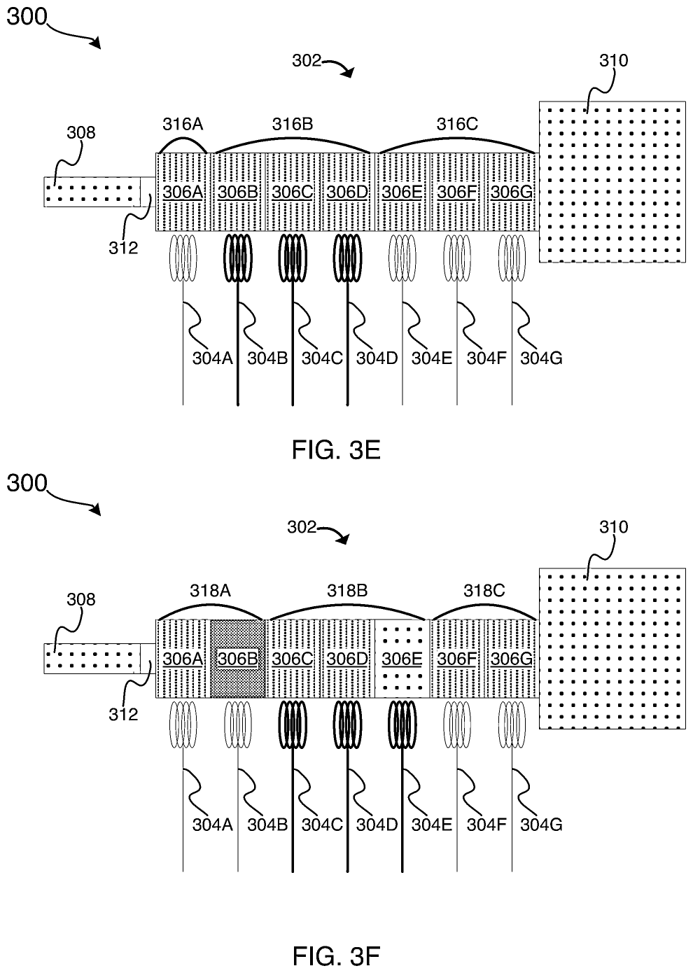

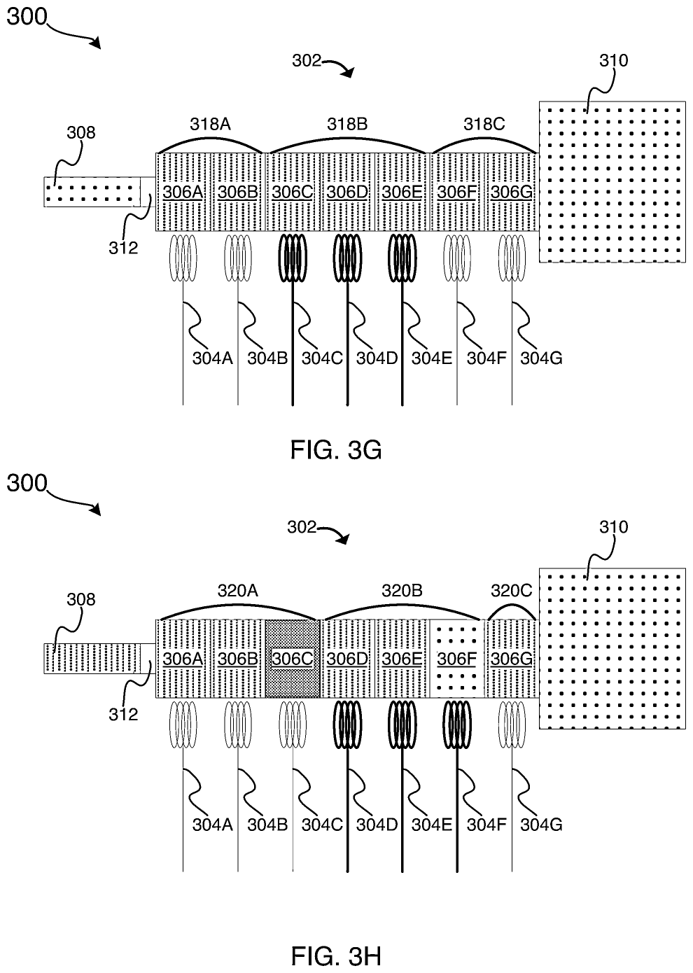

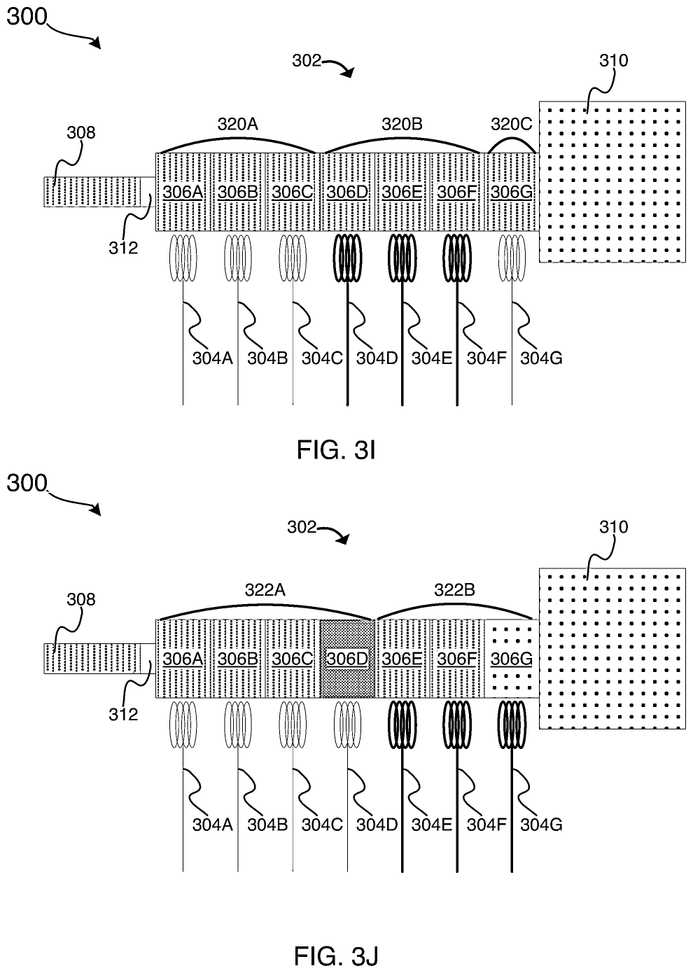

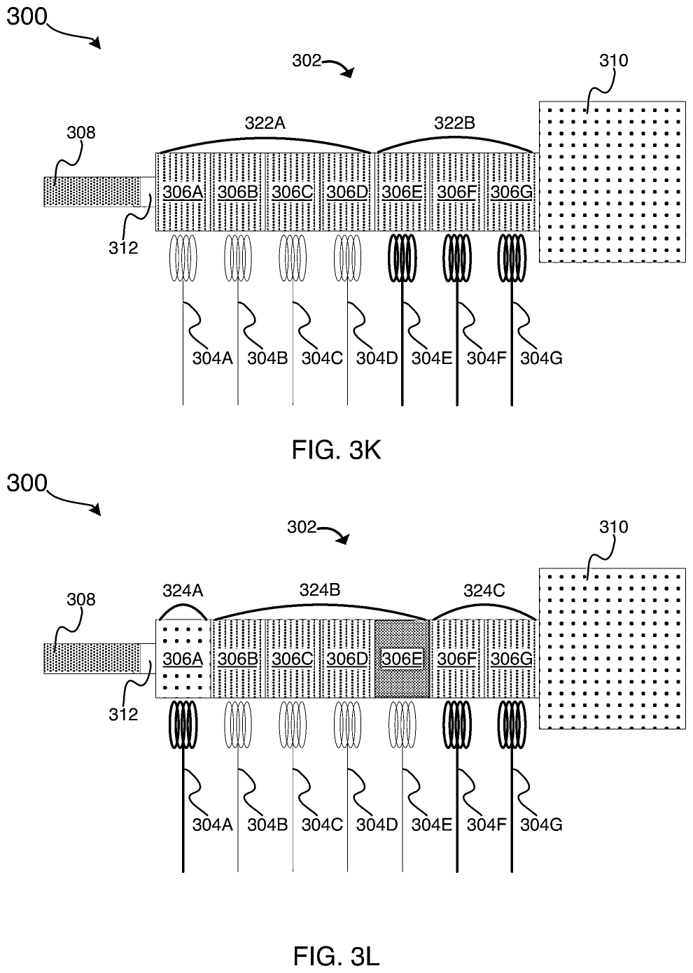

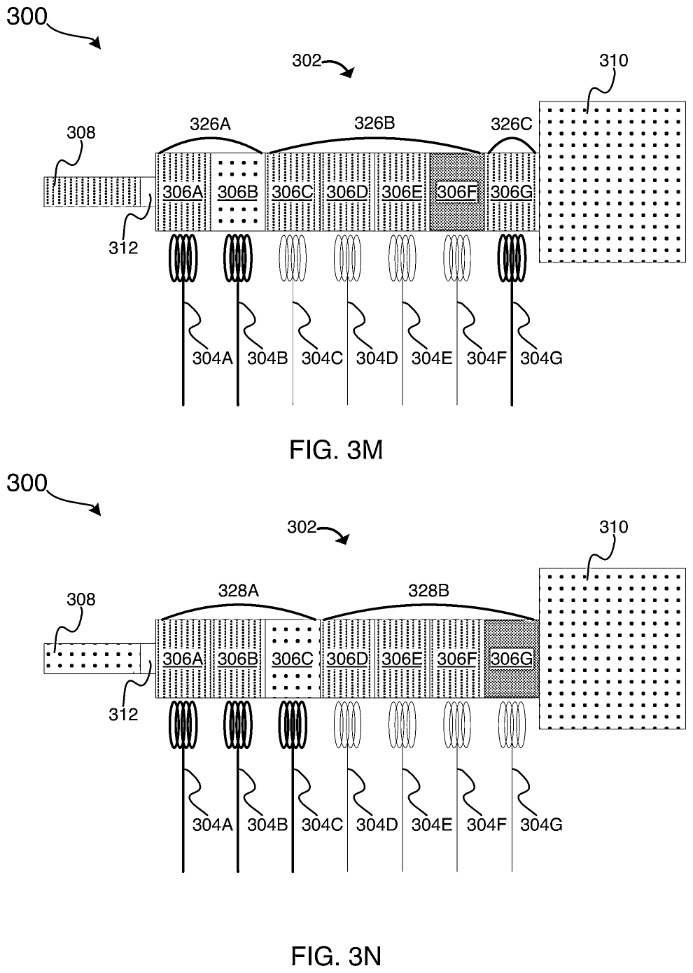

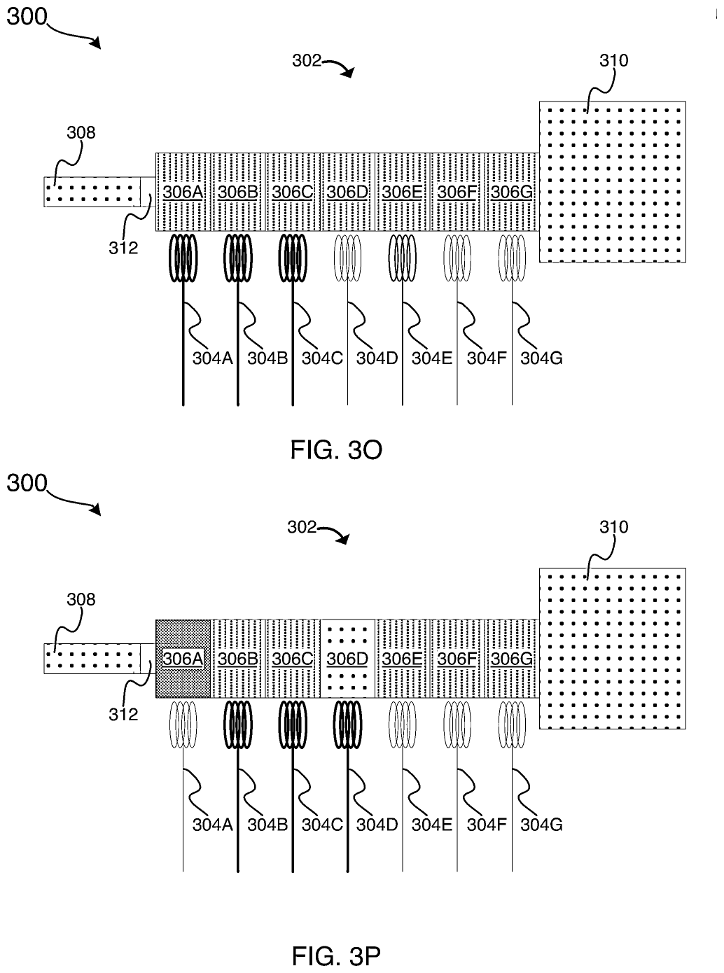

As noted above, some embodiments of the present disclosure can also address some of the issues described above by utilizing multiple localized magnetic fields to operate a magnetocaloric thermal transport medium as a form of heat pump. This design can be better understood by reviewing FIGS. 3A-3P.

FIGS. 3A-3P depict a cooling system 300 that comprises a magnetocaloric thermal transport medium 302 (also called “magnetocaloric medium 302”). Magnetocaloric medium 302 takes the form of a solid component of a magnetocaloric material, such as a topological semimetal. As illustrated, seven electromagnets 304A, 304B, 304C, 304D, 304E, 304F, and 304G have been placed adjacent to magnetocaloric medium 302. Specifically, each of electromagnet 304A-304G has been placed adjacent to a corresponding section of sections 306A, 306B, 306C, 306D, 306E, 306F, and 306G of magnetocaloric medium 302. As such, for example, activating electromagnet 304A would expose section 306A of magnetocaloric medium 302 to a magnetic field of sufficient strength to create a magnetocaloric effect in section 306A.

Similar to electromagnets 112-116 of FIGS. 1A-1J, electromagnets 304A-304G can be activated independently, enabling each of sections 306A-306G to be exposed to an electric field individually. As such, which magnetocaloric medium 302 is actually a single component and while the divisions between sections 306A-306G are not actually physical divisions between physical components, they can be treated as separate magnetocaloric sections for the purposes of operating cooling system 300.

Also similar to electromagnets 112-116 of FIGS. 1A-1J, electromagnets 304A-304G are depicted as simple coils for the sake of understanding, but could take various forms depending on the use case in which cooling system 300 is integrated. For example, electromagnets 304A-304G could take the form of solenoids that are placed near their respective sections, solenoids that are wrapped around their respective sections, patterned wires (e.g., electromagnet 304C could take the form of a patterned wire that has been formed on a substrate below section 306C), or flat patterned coils. In some embodiments, each of electromagnets 304A-304G could actually represent several electromagnets that may be activated together in order to expose their corresponding section to electromagnetic flux.

Magnetocaloric medium 302 is connected to heat-producing device 308 and system heat sink 310. As illustrated, thermal resistive component 312 is located between magnetocaloric medium 302 and heat-producing device 308. This may be useful to prevent heat from transferring back from magnetocaloric medium 302 back to heat-producing device 308. The form of thermal resistive component may vary depending upon the use case and design of cooling system 300. In some embodiments, for example, thermal resistive component 312 could take the form of a thin layer formed upon either (or both) of magnetocaloric medium 302 and heat-producing device 308, such as a dielectric layer. In some embodiments, thermal resistive component 312 could actually take the form of a magnetocaloric material, and may be in the form factor of a magnetocaloric switch, similar to magnetocaloric switch 104. In these embodiments, thermal resistive component 312 may even be paired with an electromagnet that is placed adjacent to it.

As noted, cooling system 300 can be operated as a magnetocaloric heat pump by utilizing the independent activation of electromagnets 304A-304G to effectively divide magnetocaloric medium 302 into different regions that exhibit different thermal conductances and heat capacities. As will be illustrated in FIGS. 3B-3P, these regions can be composed of one or more sections 306A-306G of magnetocaloric medium 302.

For example, FIG. 3B illustrates cooling system 300 after electromagnets 304A-304C have been activated, exposing sections 306A-306C to a magnetic field (or 3 local magnetic fields, depending upon the implementation). This has increased the thermal conductivity and heat capacity of sections 306A-306C. This effectively creates two regions of magnetocaloric medium 302: region 314A and region 314B. Because it is composed of sections 306A-306C, all of which are exposed to a magnetic field, region 314A is in a condition to accept heat from its surrounding environment. This change is illustrated by the reduced density in the dots that fill sections 306A-306C.

The sections of region 314A are being exposed to a magnetic field, and so region 314 may be referred to as an “activated” region. The sections of region 314B, on the other hand, are not exposed to a magnetic field, and so region 314B may be referred to as a “deactivated” region. Further, because section 306D is the next section that is downstream (i.e., toward system heat sink 310) of the activated region (region 314A), it may be referred to herein as the leading inactive section. Finally, because section 306A is the most upstream (i.e., toward heat-producing device 308) section of the activated region, it may be referred to herein as the trailing active section.

The outcome of this change is illustrated in FIG. 3C. Heat has spread from heat-producing device 308 to sections 306A-306C of magnetocaloric medium 302. The spread has occurred through thermal resistive component 312. This may be due in part to the thickness of thermodynamic resistive component 312, the composition of thermal resistive component 312, and the magnitude of the excess heat energy capacity in sections 306A-306C.

As a result of the heat spread, heat-producing device 308 has cooled significantly, illustrated in FIG. 3C by the decreased density of dots that fill heat-producing device 308. Further, because the heat capacity of sections 306A-306C has been largely filled by the heat spread, the density of the dots that fill sections 306A-306C is increased in FIG. 3C.

FIG. 3D depicts a next stage of cooling heat-producing device 308 with cooling system 300. Specifically, electromagnet 304A has been deactivated, whereas electromagnet 304D has been activated. This has isolated section 306A from the magnetic field that was previously increasing its heat capacity, and exposed section 306D, the previous leading inactive section, to a magnetic field that has increased its heat capacity.

This change has effectively created 3 regions of magnetocaloric medium 302: region 316A, region 316B, and region 316C. Regions 316A and 316C are similar in that they are not being exposed to a magnetic field, and are thus deactivated regions. Region 316B is being exposed to a magnetic field, and is thus an activated region. Region 316B can be thought of as region 314A having been shifted towards system heat sink 310. As will be described below, that shift will also tend to pump the heat that was previously in region 314A to region 316B.

Isolating section 306A from a magnetic field has resulted in in section 306A containing excess heat energy. That change is illustrated in FIG. 3D as an increase in the density of the dots that fill section 306A. Because thermal resistive component 312 is between heat-producing device 308 and section 306A, the excess heat will be discouraged from returning to heat-producing device 308. Rather, the excess heat is likely to spread to region 316B of magnetocaloric medium 302.

Exposing section 306D to a magnetic field has resulted in section 306D containing excess heat capacity. That change is illustrated in FIG. 3D as a decrease in the density of the dots that fill section 306D. This change has put section 304D of magnetocaloric medium 302 into a condition to accept heat energy from its environment, such as sections 306B and 306C. This also enables the excess heat energy from section 306A to spread to region 316B.

The effect of this heat spread is illustrated in FIG. 3E. In FIG. 3E, the excess heat from section 306A has spread into the sections of region 316B. Further, the heat has equalized between the sections of region 316B. This is illustrated by the density of the dots that fill section 306A increasing and the density of the dots that fill section 306E increasing to the same level as sections 306C and 306D. In other words, as shown in FIG. 3E, the heat that was originally transferred to region 314A from heat-producing device 308 has been pumped into region 316B through the manipulation of electromagnets 304A-304D.

FIG. 3F depicts a next stage of cooling heat-producing device 308 with cooling system 300. Specifically, electromagnet 304B has been deactivated and electromagnet 304E has been activated. This creates a similar result to the activations and deactivations in FIG. 3D. Specifically, section 306B is now isolated from a magnetic field, similar to section 306A, and contains excess heat energy. Section 306B is in a condition to spread heat to its surrounding environment. Section 306E is now exposed to a magnetic field, similar to sections 306C and 306D, and is in a condition to accept heat from its surrounding environment.

This has effectively divided magnetocaloric medium 302 into 3 regions: region 318A, region 318B, and region 318C. Continuing the pattern from FIG. 3D, region 318B can be thought of as region 316B having been shifted towards system heat sink 310. This will, again, shift the heat that was extracted from heat-producing device 308 towards system heat sink 310. Specifically, heat will spread from sections 306C and 306D into section 306E, and the excess heat in 306B will spread into region 318B.

The effect of this heat spread is illustrated in FIG. 3G. In other words, as shown in FIG. 3E, the heat that was originally transferred to region 314A from heat-producing device 308 has been pumped into region 316B, and now into region 318B, all through the manipulation of electromagnets 304A-304D.

FIG. 3H depicts a next stage of cooling heat-producing device 308 with cooling system 300. Continuing the pattern of the previous figures, the previous leading section, section 306F, has been exposed to a magnetic field and the previous trailing active section, section 306C, has been isolated from a magnetic field. This has effectively divided magnetocaloric medium 302 into deactivated regions 320A and 320C and activated region 320B.

Of note, FIG. 3H also illustrates an increase in the density of the dots that fill heat-producing device 308. This may be due to the operation of heat-producing device 308 during the heat-pump operations of FIGS. 3B-3H.

FIG. 3I illustrates the effect of the cooling stage of FIG. 3H. Specifically, excess heat energy has spread from section 306C into region 320B, and heat energy has equalized between the sections of region 320B (sections 306D-306F).

FIG. 3J depicts a next stage of cooling heat-producing device 308 with cooling system 300. Specifically, electromagnet 304D has been deactivated and electromagnet 304G has been activated. This has divided magnetocaloric medium 302 into deactivated region 322A and activated region 322B. Of note, activated region 322B is, as illustrated, directly connected to system heat sink 310. Thus, while section 306G currently has excess heat capacity, the heat within activated region 322B can now spread to system heat sink 310. In fact, FIGS. 3L-3P will illustrate deactivations of electromagnets 304E-304G, effectively pumping the heat into system heat sink 310.

FIG. 3K depicts the initial result of this stage. Excess heat from section 306D has spread to region 322B, and heat has equalized throughout region 322B. Of note, at this point heat could begin to spread from region 322B to system heat sink 310. However, that heat spread may be slow, because none of sections 306E through 306G have excess heat energy due to the activations of electromagnets 304E-304G. Thus, in some instances, all of electromagnets 304E 304G could be deactivated together at this point, decreasing the heat capacity of sections 306E 306G. This would create excess heat energy within sections 306E-306G, encouraging the spread of heat from region 322B to system heat sink 310.

However, deactivating electromagnets 304E-304G simultaneously would also decrease the thermal conductivity of the magnetocaloric material within sections 306E-306G. This may potentially slow the heat spread from, for example, the left side of section 306E towards the right side of 306G and into system heat sink 310. As a result, excess heat energy may be more likely to spread from section 306E into section 306D. For this reason, it may be more beneficial in some instances to continue to deactivate electromagnets 304E-304G in order, effectively pumping heat into system heat sink 310.

Thus, FIG. 3L depicts a next stage of cooling heat-producing device 308 with cooling system 300. Specifically, electromagnet 304E has been deactivated, causing section 306E to contain excess heat energy. Because sections 306F and 306G are in activated region 324C, and section 306D is in deactivated region 324B, sections 306F and 306G have significantly higher thermal conductance than section 306D. As a result, the excess heat energy in section 306E will tend to spread to sections 306F and 306G. This may result in sections 306F and 306G containing excess heat energy, but that heat energy could then be spread to system heat sink 310.

Of note, FIGS. 3K and 3L illustrate that heat-producing device 308 has continued to increase its heat energy. FIG. 3L also illustrates the activation of electromagnet 304A, increasing the heat capacity and thermal conductance of section 306A. This has resulted in a second activated region, activated region 324A. Note that in some use cases, electromagnet 304A could be automatically activated upon deactivation of electromagnet 304E, automatically restarting the pattern of electromagnet activation first illustrated in FIG. 3B. In some use cases, electromagnet 304A could be activated upon sensing that heat-producing device 308 has crossed an upper temperature threshold.

Further, in some instances it may be beneficial to activate all of electromagnets 304A-304C together in FIG. 3L, as was illustrated in FIG. 3B. Or, alternatively, electromagnets 304A-304B could be activated together in FIG. 3L. However, only electromagnet 304A is illustrated as activated here in FIG. 3L in an effort to more fully depict the wave nature of the heat-pump operation of cooling system 300.

Thus, FIG. 3M depicts a next stage of cooling heat-producing device 308 with cooling system 300. In FIG. 3M, electromagnet 304F has been deactivated, causing section 306F to contain excess heat energy. That excess heat energy would spread to section 306G, which has significantly higher thermal conduction and heat capacity. This may expedite the spread of heat that was previously in section 306G to system heat sink 310.

Further, electromagnet 304B has been reactivated in FIG. 3M. As a result, heat can continue to spread from heat-producing device 308 into magnetocaloric medium 302 (specifically, into sections 306A and 306B of region 326A). As illustrated, magnetocaloric medium 302 has been divided into 3 regions in FIG. 3M: regions 326A, 326B, and 326C.

FIG. 3N depicts a next stage of cooling heat-producing device 308 with cooling system 300. In FIG. 3N, electromagnet 304G has been deactivated, causing section 306G to contain excess heat energy. However, because section 306F is also in a deactivated region (region 328B), the section 306F has low thermal conductance. For this reason, most of the excess heat energy within section 306G will spread to system heat sink 310.

Further, electromagnet 304C has been reactivated, increasing the heat capacity of 306C. As a result, the heat capacity of the region that is most connected to heat-producing device 308 has increased, encouraging further spread of heat from heat-producing device 308 to magnetocaloric medium 302. As a result, heat-producing device 308 has further cooled.

FIG. 3O depicts cooling system 300 after the heat spread discussed in connection to FIG. 3N. Specifically, the excess heat from section 306G has been transferred into system heat sink 310, heat has further transferred from heat-producing device 308 into sections 306A-306C, and the heat within sections 306A-306C has equalized. In other words, cooling system 300 in FIG. 3O is illustrated in a similar state as it was illustrated in FIG. 3C. From this point forward, the heat-pump operation of cooling system 300 could continue as originally illustrated in FIGS. 3D-3N.

To further illustrate the potentially cyclic nature of cooling system 300, FIG. 3P depicts a next stage of operating cooling system 300, resembling the stage originally illustrated in FIG. 3D. In some use cases, cooling system 300 could be continuously looped through the stages illustrated in FIGS. 3B-3N during the operation of heat-producing device 308.

Of note, most of FIGS. 3A-3P depicted activating 3 electromagnets in each stage. This may be ideal in some use cases, but was done in this disclosure to effectively illustrate the heat-pump nature of operating cooling system 300. For this reason, embodiments of the present disclosure should not be interpreted as reading only on heat-pump type cooling systems that activate sets of 3 electromagnets simultaneously.

Similarly, FIGS. 3A-3P depicted activating the electromagnet corresponding to the leading inactive section (e.g., section 306D in FIG. 3O) at the same time as deactivating the electromagnet of the trailing active section (e.g., section 306A in FIG. 3O). While this was also done in this disclosure to effectively illustrate the heat-pump nature of operating cooling system 300, there may be benefits to this simultaneous activation and deactivation in some use cases. That said, in other use cases, activating and deactivating these electromagnets separately may be beneficial.

For example, in some use cases, an electromagnet adjacent to a leading inactive section could be activated before deactivating the electromagnet adjacent to a trailing active section. In FIG. 3O, for example, this would resemble activating electromagnet 304D before deactivating electromagnet 304A. In some use cases, this may encourage heat to spread from sections 306A-306C into 306D before section 306A is isolated from a magnetic field. This could, in turn, discourage heat from spreading backwards from section 306A back into heat-producing device 308 upon the later deactivation of electromagnet 304A. However, this may also encourage heat to spread into section 306D from section 306E because the heat from section 306A would not yet be pumped out of section 306A. For this reason, this strategy may be most useful when the leading inactive section is directly connected to the system heat sink (for example, as illustrated in FIG. 3I.

Similarly, in some use cases, an electromagnet adjacent to a trailing active section could be deactivated before activating the electromagnet adjacent to a leading inactive section. In FIG. 3O, for example, this would resemble deactivating electromagnet 304A before activating electromagnet 304D. In some use cases, this may encourage heat to spread into the sections of the activated region (e.g., sections 306B and 306C) before activating the leading inactive section (e.g., section 306D). This may discourage heat from spreading backwards from downstream sections into the leading inactive section once that section is exposed to a magnetic field (e.g., discourage heat from spreading backwards from section 306E to 306D upon activation of electromagnet 304D).

However, this could also encourage heat to spread from the trailing active section to upstream sections, or to the heat-producing device, before the leading inactive section is exposed to a magnetic field (e.g., encourage heat to spread from section 306A to heat-producing device 308 before section 304D is exposed to a magnetic field). For this reason, this strategy may be least useful when the trailing active section is proximately connected to the heat-producing device with respect to the other sections (e.g., is either directly connected to the heat-producing device or connected to a thermal resistive material that is directly connected to the heat-producing device).

Could activate leading electromagnet before deactivating trailing electromagnet. That would encourage heat spread into leading section earlier, preventing heat from trailing section from spreading backwards from downstream sections. But this might encourage heat to spread into the leading section from the next section. Could also deactivate trailing edge before activating leading edge. This could encourage heat to spread into leading region before activating the leading edge. This could prevent heat from spreading into leading section backwards. But this could encourage heat to spread from the trailing section to upstream sections.

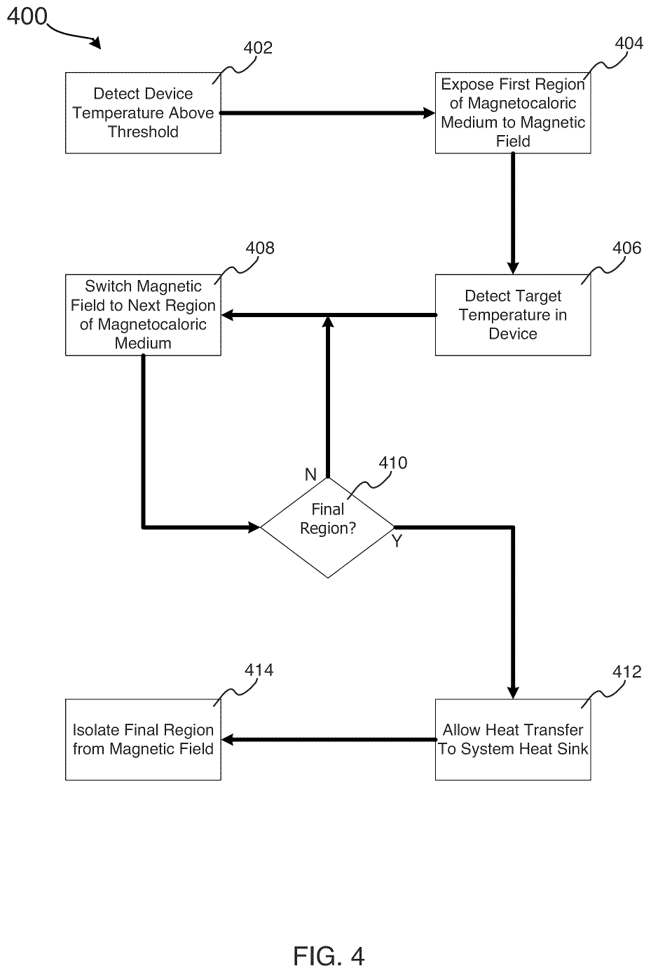

For the sake of understanding, FIG. 4 illustrates an example process of using a cooling system that comprises a set of electromagnets that can be used to pump heat through a magnetocaloric medium, similar to cooling system 300. Method 400 begins in block 402, in which a device temperature for a heat-producing device is detected to be above a threshold temperature. This may take the form of, for example, detecting a temperature of heat-producing device 308.

Of note, in some methods of operating a cooling system similar to cooling system 300, block 402 may be considered optional. For example, if the cooling system is continuously operated in a heat-pump cycle during the operation of the heat-producing device, block 402 may be unnecessary.

Method 400 continues in block 404, in which a first region of the magnetocaloric medium is exposed to a magnetic field (or a set of magnetic fields). This may take the form for example, of activating a set of electromagnets that are adjacent to the region, such as electromagnets 304A-304C that are adjacent to region 314A in FIG. 3B. In some embodiments, this set of electromagnets may include a single electromagnet, whereas in other embodiments, the set may include more than one electromagnet.

Method 400 continues in block 406 in which a target temperature is detected in the heat-producing device. This may resemble, in some embodiments, detecting that heat-producing device 308 has reached a threshold low temperature in FIG. 3C. Block 406 may be useful, in some embodiments, to ensure that the heat-producing device has cooled to a desired temperature before the section of the magnetocaloric medium that is closest to that heat-producing device is isolated from a magnetic field. In some embodiments, however, the electromagnets adjacent to the magnetocaloric medium may be activated and deactivated as part of a periodic pattern or timer. This may take the form of, for example, deactivating electromagnet 304A in FIG. 3D after a pre-determined period of time has elapsed since having activated electromagnet 304A in FIG. 3B.

Method 400 continues in block 408 in which the cooling system switches the magnetic field (or set of fields) to the next region of magnetocaloric medium. In some embodiments, this may take the form of deactivating one or more electromagnets that are adjacent to a section of the magnetocaloric medium in the first region and activating one or more electromagnets that are adjacent to a section of the magnetocaloric medium in the next region. In some embodiments, the next region may overlap with the first region, as shown in regions 314A and 316B of FIGS. 3C and 3D. In other embodiments the two regions may not overlap, such as region 314A and 320B of FIGS. 3C and 3H.

Method 400 continues in block 410 in which it is determined whether the most-recent region of the magnetocaloric medium to which the magnetic field was switched in block 408 is the final region in the magnetocaloric medium. In some embodiments, this may involve confirming that the region directly connects to the system heat sink. In other embodiments, this may involve confirming that the region corresponds to the very last electromagnet before the system heat sink (e.g., magnet 340G of FIG. 3M).

If it is determined in block 410 that the region is not the final region (e.g., region 320B of FIG. 3H) method 400 returns to block 408 to iterate through blocks 408 and 410. If, on the other hand, it is determined in block 410 that the region is the final region, method 400 proceeds to block 412 in which the cooling system allows the heat from the final region to transfer to the system heat sink. In some embodiments, this may take the form of waiting for a per-determined amount of time. In some embodiments, this may take the form of waiting until the magnetocaloric medium has cooled to a threshold low temperature in the final region.

Once heat has been allowed to transfer to the system heat sink in block 412, method 400 proceeds to block 414, in which the final region is isolated from the magnetic field.

In some embodiments, method 400 may iterate through blocks 402-414 again after performing block 414. In some embodiments, method 400 may proceed to block 404 after performing block 414. In other embodiments, method 400 may end after block 414.

Some embodiments of the present disclosure may involve isolating relatively massive thermal transport media from a magnetic field in order to put those media in a condition to transfer the heat energy stored within to their surrounding environment. However, as noted, isolating a magnetocaloric thermal transport medium from a magnetic field not only decreases its heat capacity, but also its thermal conductivity. In some particularly massive media, this may result in a very slow exit of heat from the medium.

For example, in some embodiments of the present disclosure, a magnetocaloric heat sink, such as magnetocaloric heat sink 102, or a section of a magnetocaloric medium, such as section 306A, is isolated from a magnetic field. However, if magnetocaloric heat sink 102 or section 306A has relatively large dimensions, heat that is located in the very left of the sink/section (e.g., heat in the top left corner of magnetocaloric heat sink 102 in FIG. 1H) may have a large distance to travel through the rest of the body of the sink/section before reaching the next thermal transport medium (e.g., magnetocaloric switch 106 of FIG. 1H). Because the material of the medium would have a low thermal conductivity, it may take a long time for heat energy to exit the medium.

In such embodiments, it may be beneficial to design a thermal transport medium with a thermal transport supplement to increase the rate at which heat energy is able to exit the medium.

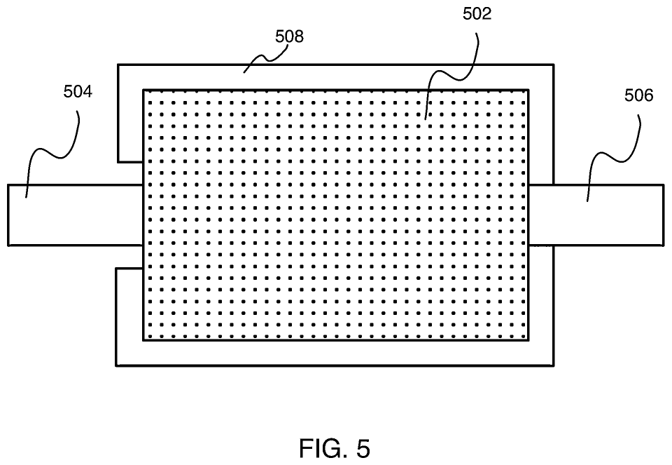

Such an embodiment is illustrated in FIG. 5. FIG. 5 illustrates thermal transport medium 502. Thermal transport medium 502 is illustrated as a magnetocaloric heat sink, but may also take the form of a section of a magnetocaloric medium. Thermal transport 502 connects to magnetocaloric switch 504 on the left side and magnetocaloric switch 506 on the right side. Of note, in embodiments in which thermal transport medium 502 takes the form of a section of a magnetocaloric medium, magnetocaloric switch 506 may take the form of another section of the magnetocaloric medium or of a system heat sink. Similarly, magnetocaloric switch 504 may take the form of another section of the magnetocaloric medium, a heat-producing device, or a thermal resistive component.

Thermal transport medium 502 also illustrates thermal transport supplement 508 applied thereto. Thermal transport supplement 508 may take the form of a material with high thermal conductance that is applied to the surface of thermal transport medium 502. Thermal transport supplement 508 may, for example, take the form of a copper wire wrapped around thermal transport medium 502 or a layer of copper that was formed upon thermal transport medium 502.

Thermal transport supplement 508 may serve to provide a low-resistance path for heat to spread from one side of thermal transport medium 502 to the other. For example, if thermal transport medium 502 were isolated from a magnetic field, the heat capacity of thermal transport medium 502 would drop, resulting in excess heat energy within thermal transport medium 502. However, the presence of thermal transport supplement provides an efficient path for some heat energy to spread to magnetocaloric switch 506. Specifically, for example, rather than the requiring the excess heat energy on the left side of thermal transport medium 502 to travel throughout the low-conductance material of the other portions of thermal transport medium 502, that excess heat energy could spread to the thermal transport supplement 508 and from that point move throughout thermal transport supplement 508 and to magnetocaloric switch 506 relatively quickly.

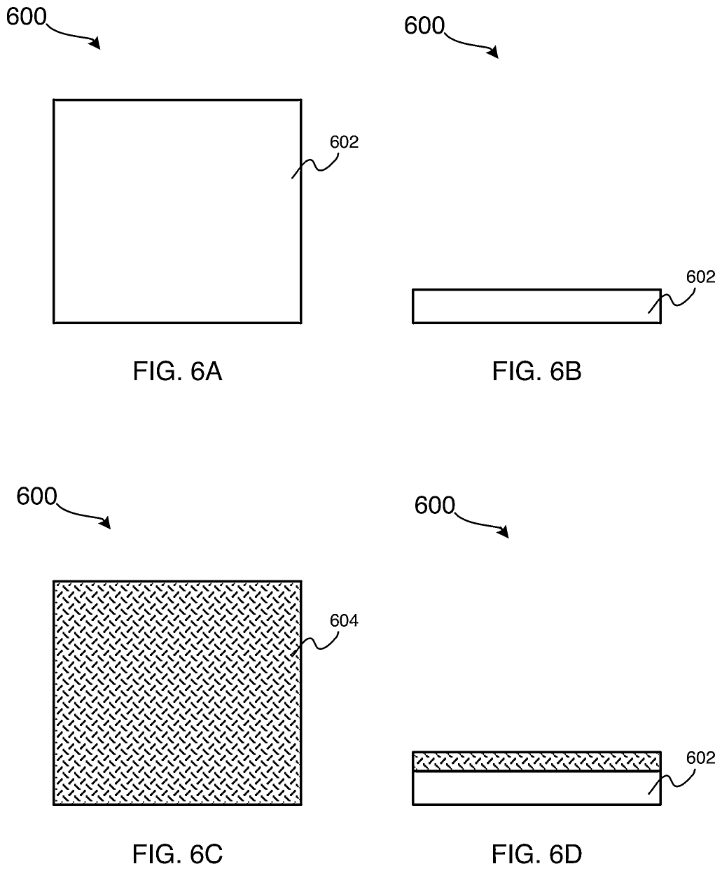

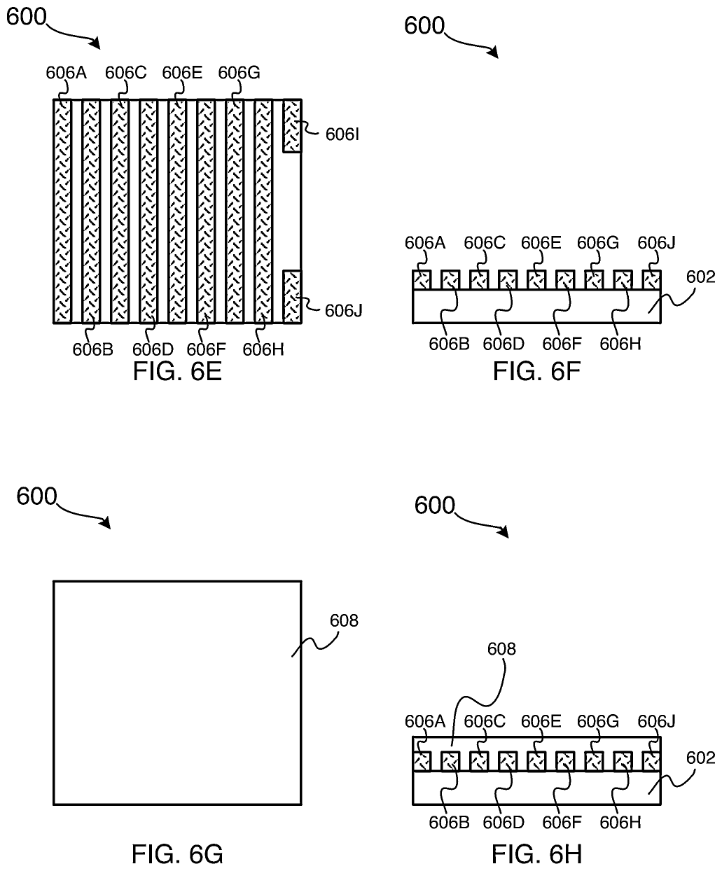

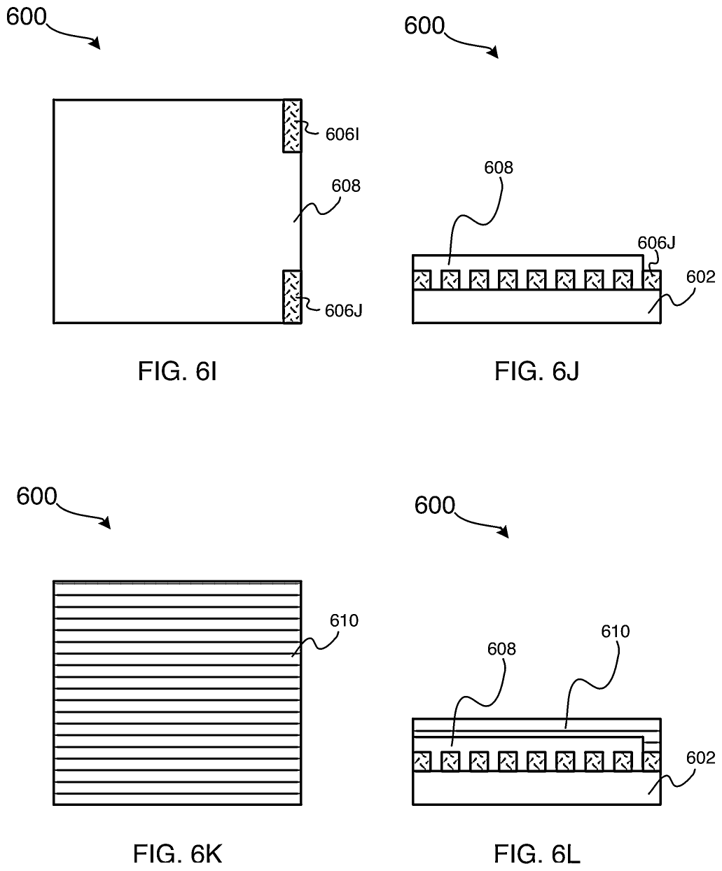

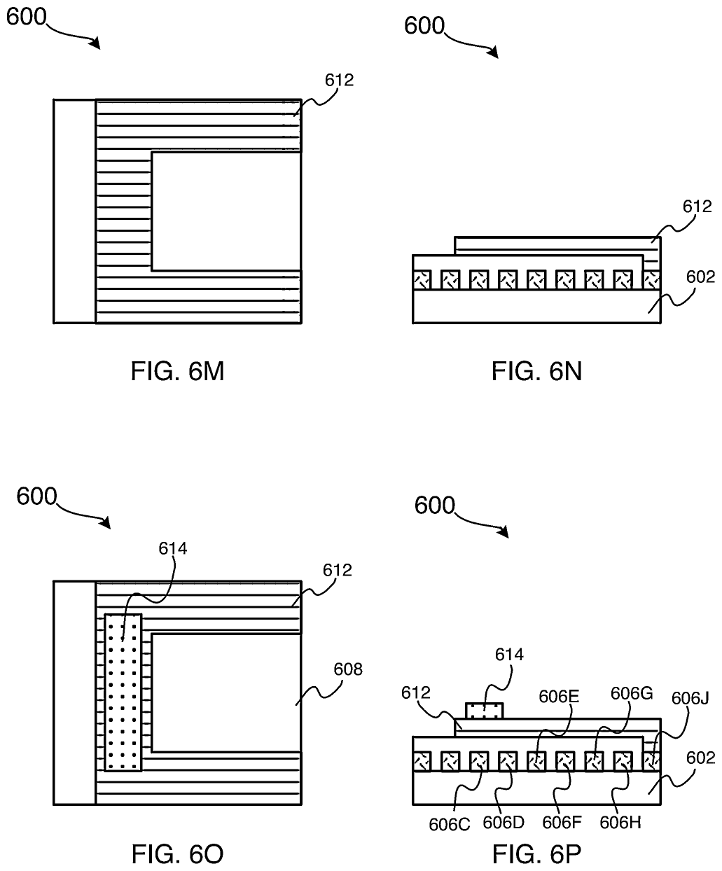

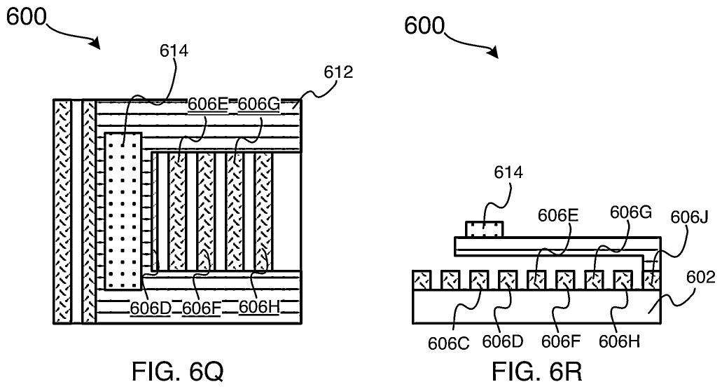

As noted, embodiments of the present disclosure involve independently activating one or more sets of electromagnets to cause a magnetocaloric medium to act as a heat pump. To aid in the understanding of those embodiments, FIGS. 6A-6R illustrate various stages of forming such cooling systems.

FIGS. 6A and 6B illustrate two views of a first stage of forming cooling system 600. Specifically, FIG. 6A depicts a top-down view (i.e., a plan view) of cooling system 600, and FIG. 6B depicts a side view (i.e., a cross sectional view) of cooling system 600. Indeed, throughout FIGS. 6A-6R, figures found on the left side of the sheet depict a top-down view of cooling system 600, and figures found on the right side of the sheet depict a side view of cooling system 600. In this first stage, a substrate 602 upon with the cooling system can be formed is provided.

FIGS. 6C and 6D depict two views of a second stage of forming cooling system 600. In this second stage, a layer 604 of electrically conductive material, such as copper or gold, is formed upon substrate 602. For example, layer 604 may have been formed using chemical vapor deposition, sputtering, or atomic layer deposition using a precursor.

FIGS. 6E and 6F depict two views of a third stage of forming cooling system 600. In this third stage, layer 604 has been patterned into a series of metal lines 606A-606J (i.e., patterned wires). This patterning may have been performed, for example, by depositing a photomask over the portions of layer 604 that is represented by metal lines 606A-606J and performing a directional etch (e.g., a reactive ion etch) on the portions of layer 604 that is not covered by the photo mask.

FIGS. 6G and 6H depict two views of a fourth stage of forming cooling system 600. In this fourth stage, dielectric layer 608 has been formed over substrate 602 and metal lines 606A-606J. In some embodiments discussed below, it may be beneficial for dielectric layer 608 to be a thin layer (e.g., 50 nm) and formed out of a material with very low thermal conductivity (e.g., SiO₂).

FIGS. 6I and 6J depict two views of a fifth stage of forming cooling system 600. In this fifth stage, dielectric layer 608 is etched above metal lines 6061 and 606J, providing access to metal lines 6061 and 606J for device contacts. This may have been performed using a directional etch.

FIGS. 6K and 6L depict two views of a sixth stage of forming cooling system 600. In this sixth stage, a layer of a magnetocaloric material 610 is layered upon dielectric layer 608 and contacts 6061 and 606J. Magnetocaloric material 610 may take the form of, for example, a topological semimetal such as niobium phosphide.

FIGS. 6M and 6N depict two views of a seventh stage of forming cooling system 600. In this seventh stage, the layer of magnetocaloric material 610 has been patterned into thermal transport medium 612. This may have been performed, for example, by applying a photoresist layer over the portions of magnetocaloric material 610 that is represented by thermal transport medium 612 in FIG. 6M and performing a directional etch over the remaining portions of magnetocaloric material 610.

FIGS. 6O and 6P depict two views of an eighth stage of forming cooling system 600. In this eighth stage, a heat-producing device 614 has been patterned upon thermal transport medium 612. In this stage, the operation of cooling system 600 can be understood. Specifically, metal lines 606C-606J take the form of electromagnets that can be activated (e.g., current can be run through them) to create a magnetic field above them. These electromagnets can be independently controlled to cause corresponding sections of thermal transport medium 612 to be exposed to a magnetic field and their heat capacities to increase.

For example, by activating electromagnet 606C, the heat capacity of thermal transport layer 612 directly below heat-producing device 614 can be significantly increased, increasing the spread of heat energy from heat-producing device 614 to thermal transport medium 612. Electromagnets 606C-606J could then be activated in a similar wave-type pattern to the electromagnets in FIG. 3, causing that heat energy to be pumped to the right and out of thermal transport medium 612.

FIGS. 6Q and 6R depict an optional ninth stage of forming cooling system 600. In this optional ninth stage, dielectric layer 608 has been removed. This may beneficially increase thermal insulation of the heat energy produced by heat-producing device 614. In other words, removing dielectric layer 608 may help to prevent the heat energy that spreads from heat-producing device 614 to thermal transport medium 612 from spreading further to metal lines 606C-606H.

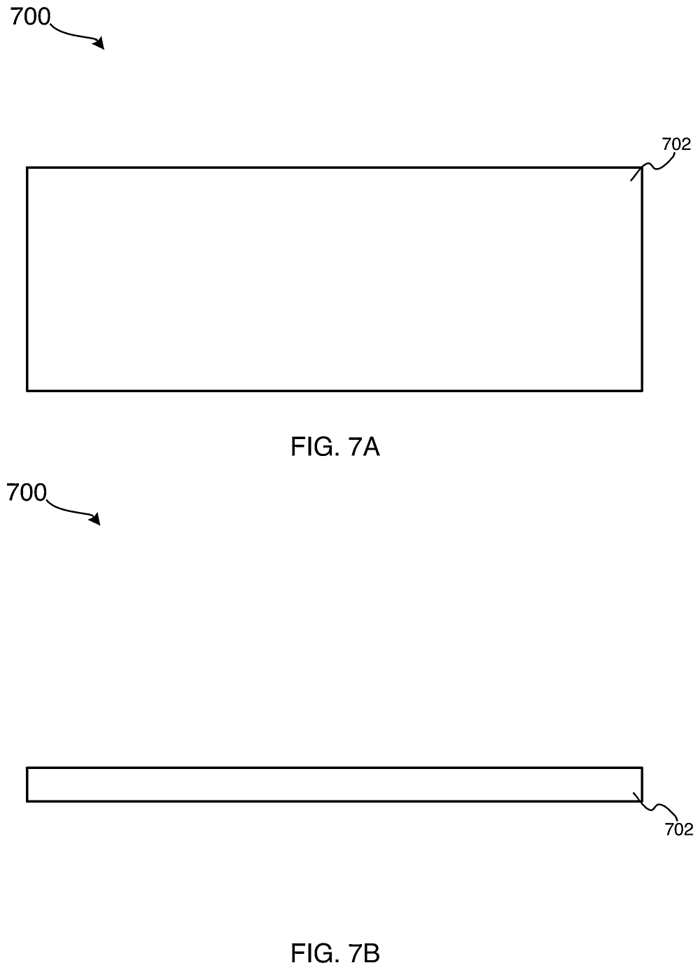

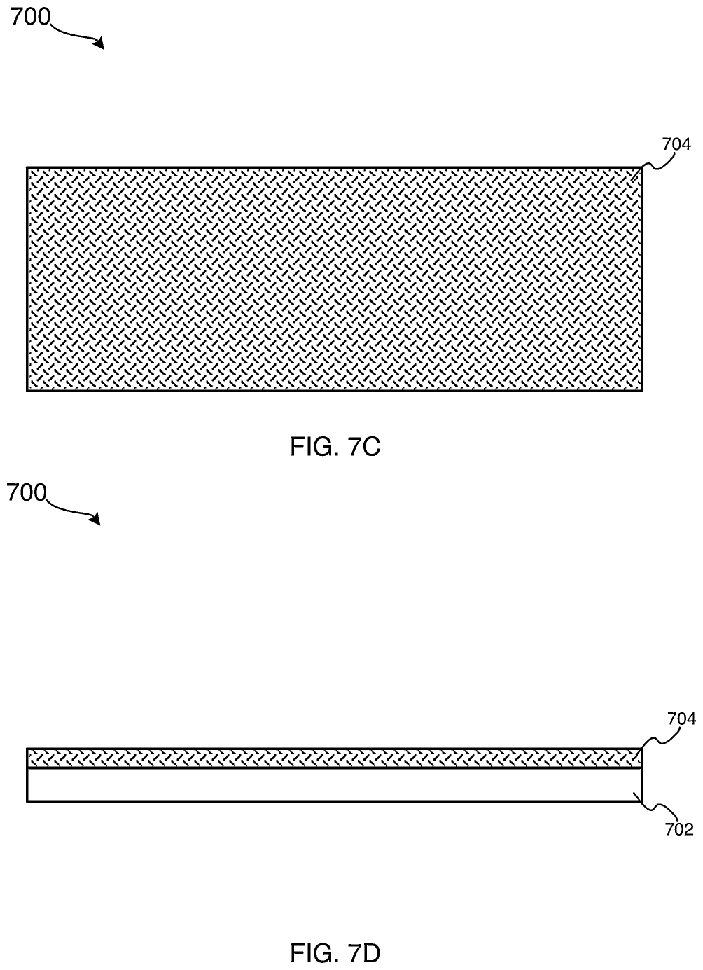

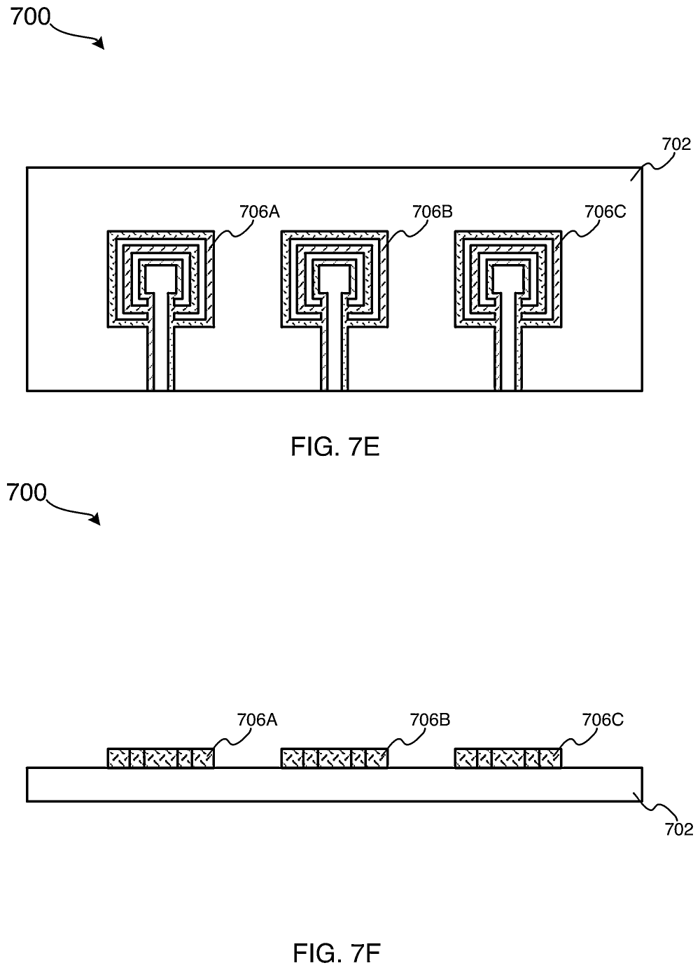

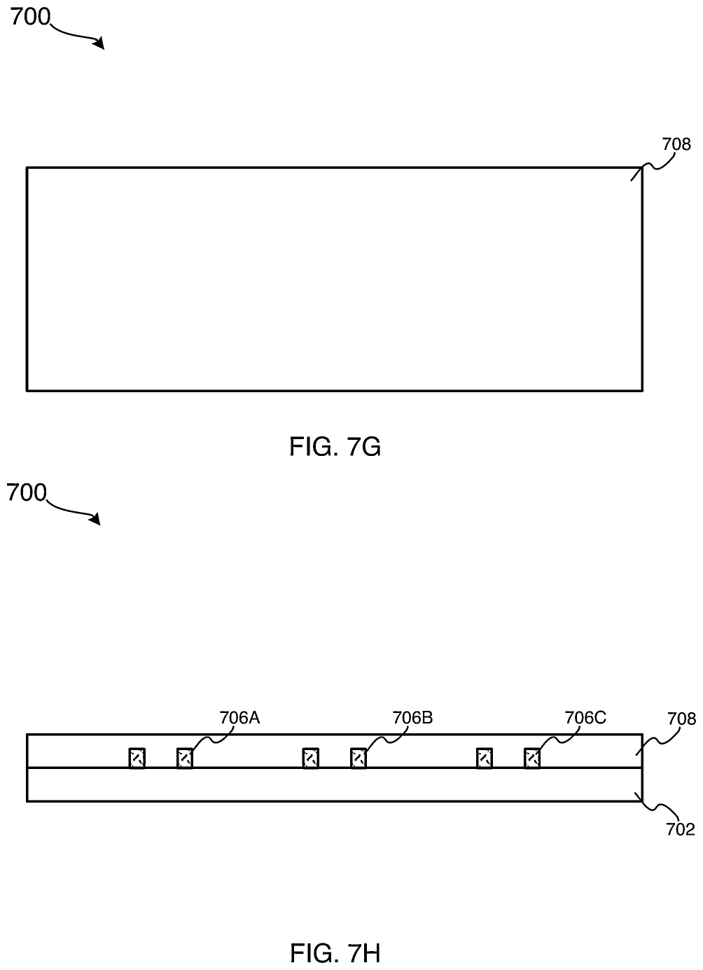

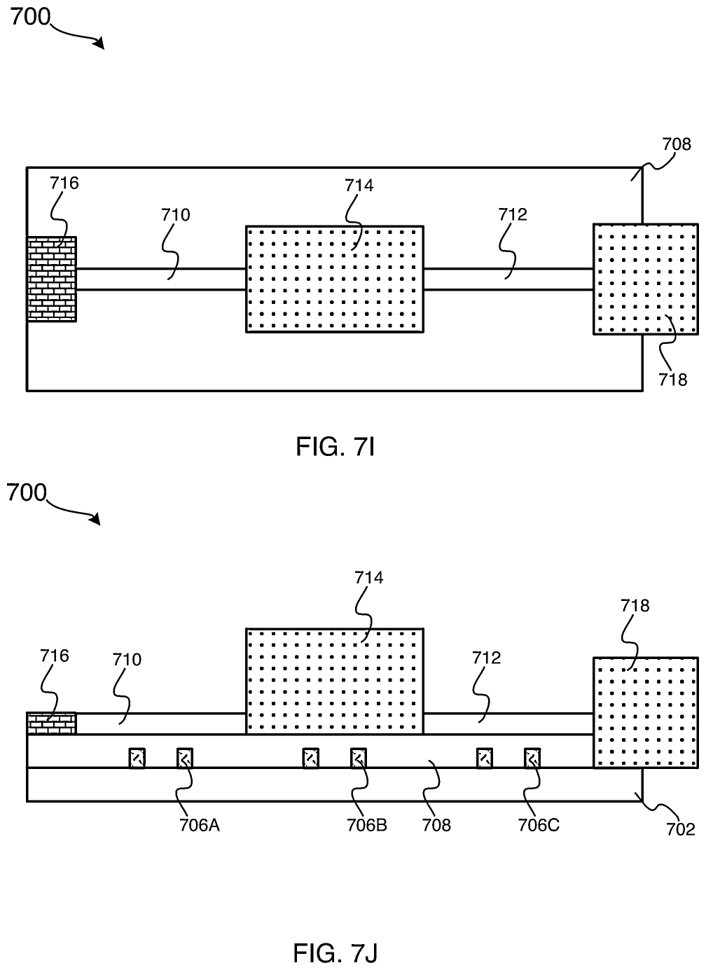

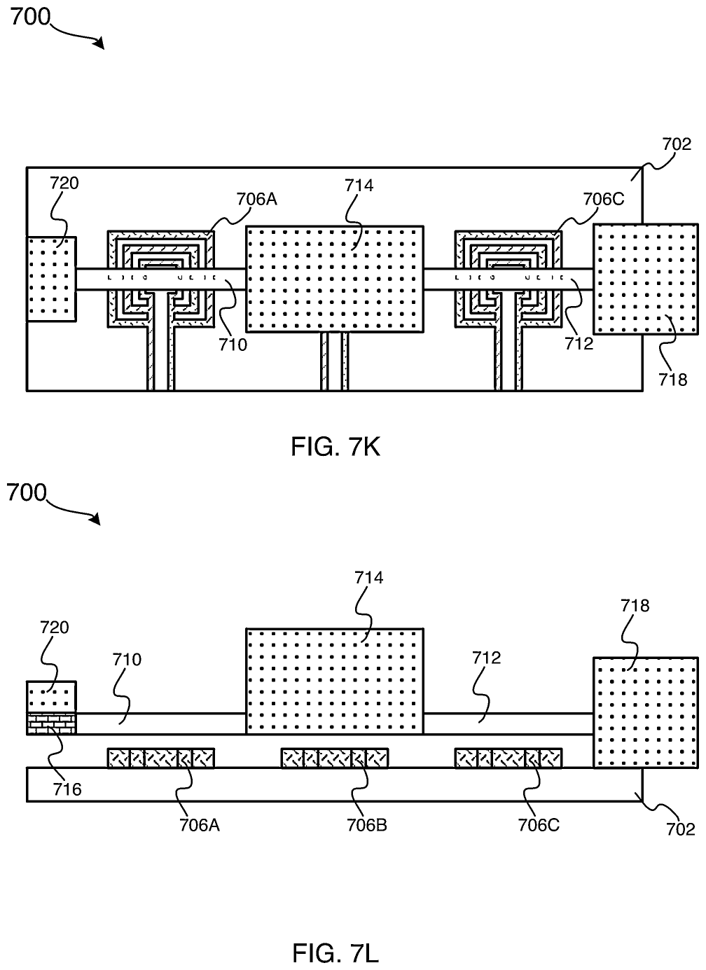

As noted, some embodiments of the present disclosure involve a cooling system with a magnetocaloric heat sink two magnetocaloric switches. To aid in the understanding of those embodiments, FIGS. 7A-7L illustrate various stages of forming such cooling systems.

FIGS. 7A and 7B illustrate two views of a first stage of forming cooling system 700. Specifically, FIG. 7A depicts a top-down view (i.e., a plan view) of cooling system 700, and FIG. 7B depicts a side view (i.e., a cross sectional view) of cooling system 700. Indeed, throughout FIGS. 7A-7L, figures found on the top side of the sheet depict a top-down view of cooling system 700, and figures found on the bottom side of the sheet depict a side view of cooling system 700. In this first stage, a substrate 702 upon with the cooling system can be formed is provided.

FIGS. 7C and 7D depict two views of a second stage of forming system 700. In this second stage, a layer 704 of electrically conductive material, such as copper or gold, is formed upon substrate 702. For example, layer 704 may have been formed using chemical vapor deposition, sputtering, or atomic layer deposition using a precursor.

FIGS. 7E and 7F depict two views of a third stage of forming cooling system 700. In this third stage, layer 704 has been patterned into microcoils 706A-706C (i.e., flat patterned metal lines in the shape of coils). This patterning may have been performed, for example, by depositing a photomask over the portions of layer 704 that is represented by microcoils 706A-706C and performing a directional etch (e.g., a reactive ion etch) on the portions of layer 704 that is not covered by the photo mask.

FIGS. 7G and 7H depict two views of a fourth stage of forming cooling system 700. In this fourth stage, dielectric layer 708 has been formed over substrate 702 and microcoils 706A-706C. In some embodiments discussed below, it may be beneficial for dielectric layer 708 to be a thin layer (e.g., 50 nm) and formed out of a material with very low thermal conductivity (e.g., SiO₂).

FIGS. 7I and 7J depict two views of a fifth stage of forming cooling system 700. In this fifth stage, magnetocaloric switches 710 and 712 and magnetocaloric heat sink 714 are patterned onto dielectric layer 708. Magnetocaloric switches 710 and 712 are both formed adjacent to microcoils 706A and 706C respectively, which would cause them to be exposed to a magnetic field when current flowed through microcoils 706A and 706C. Similarly, Magnetocaloric heat sink 714 is formed adjacent to microcoil 706B, which would cause it to be exposed to a magnetic field when current flowed through microcoil 706B.

As a person of skill in the art would appreciate, the precise method by which magnetocaloric switches 710 and 712 and magnetocaloric heat sink 714 are patterned onto substrate 708 may vary based on the implementation. For example, in embodiments in which magnetocaloric switches 710 and 712 and magnetocaloric heat sink 714 are all composed of the same magnetocaloric material (e.g., the same topological semimetal), a thick layer of that magnetocaloric material may have been deposited over the entirety of dielectric layer 708. This thick layer may have reached to the top of magnetocaloric heat sink 714 as shown in FIG. 7J.

Magnetocaloric heat sink 714 may then have been patterned by applying an etch mask over the portion of the top of the thick layer that matches the top profile of magnetocaloric heat sink 714 as illustrated in FIG. 7I. A timed directional etch, such as chemical mechanical planarization (also referred to herein as “CMP”) may then have been performed on the thick layer, reducing the height of the thick layer to the top of magnetocaloric switches 710 and 712 as shown in FIG. 7J.

Magnetocaloric switches 710 and 712 may then have been patterned by applying another etch mask over the portion of the top of the reduced thick layer that matches the top profile of magnetocaloric switches 710 and 712 as they are shown in FIG. 7I. A second directional etch may have been performed that eliminated any of the remainder of the magnetocaloric material that was not covered by the photomask. This second directional etch may have been, for example, a CMP that utilized an etchant that has a high selectivity for the magnetocaloric material over the material of dielectric layer 708, causing dielectric layer 708 to act as an etch stop. The magnetocaloric material that would be remaining after these etches would be in the shapes of magnetocaloric switches 710 and 712 and magnetocaloric heat sink 714. The photomasks on top of the magnetocaloric switches 710 and 712 and magnetocaloric heat sink 714 could then be removed.

In some, however, magnetocaloric switches 710 and 712 and magnetocaloric heat sink 714 could patterned separately. For example, in some embodiments magnetocaloric switches 710 and 712 may have been formed completely before, or completely after, magnetocaloric heat sink 714 was formed. This may be particularly useful in embodiments in which magnetocaloric heat sink 714 is not the same material as magnetocaloric switches 710 and 712.

For example, a thin layer of a first magnetocaloric material (e.g., TaAs) may have been formed upon dielectric layer 708. This thick layer may have reached to the top of magnetocaloric switches 710 and 712 as shown in FIG. 7J. Magnetocaloric switches 710 and 712 may then have been patterned by applying an etch mask over the portion of the top of the reduced thick layer that matches the top profile of magnetocaloric switches 710 and 712 as they are shown in FIG. 7I. An etch may have been performed that has a high selectivity for the first magnetocaloric material over the material of dielectric layer 708. The magnetocaloric material that would remain after this etch would be in the shapes of magnetocaloric switches 710 and 712.

A thick layer of a second magnetocaloric material (e.g., NbP) could then be formed over dielectric layer 708 and the etch mask that remained on the tops of magnetocaloric switches 710 and 712. This thick layer may have reached to the top of magnetocaloric heat sink 714 as shown in FIG. 7J.

Magnetocaloric heat sink 714 may then have been patterned by applying an etch mask over the portion of the top of the thick layer that matches the top profile of magnetocaloric heat sink 714 as illustrated in FIG. 7I. To aid in precision, some etch mask may also be applied on the portions of the thick layer that were formed over magnetocaloric switches 710 and 712, which would be raised compared to the remainder of the thick layer. A timed CMP etch could then be performed that removed all of the higher etch mask that was on the thick layer above magnetocaloric switches 710 and 712, but not the etch mask that corresponded to the top profile of magnetocaloric heat sink 714.

A third CMP could then be performed that with an etchant that has a high electivity for both etch masks upon the thick layer of the second magnetocaloric material and on the tops of magnetocaloric switches 710 and 712. The second magnetocaloric material that would remain after this etch would be in the shape of magnetocaloric heat sink 714. The etch masks on the top of magnetocaloric heat sink 714 and on the tops of magnetocaloric switches 710 and 712 could then be removed.

The fifth stage of forming cooling system 700 that is represented in FIGS. 7I and 7J also depicts a contact 716 for a heat-producing device. Contact 716 may be, for example, a copper or gold patterned onto dielectric layer 708 by application of a thin layer of contact material, an application of an etch mask, and CMP similar to the example processes described as forming magnetocaloric switches 710 and 712 and magnetocaloric heat sink 714.

The fifth stage of forming cooling system 700 that is represented in FIGS. 7I and 7J also depicts contact point 718 for a system heat sink. In some embodiments, this contact point may take the form of a metal with high thermal conductivity. In some embodiments, this contact point may actually be considered part of the system heat sink.

Contact point 718 may have been formed by first forming an etch mask over dielectric layer 708 in a pattern that is the inverse of the top-profile shape of contact point 718 as shown in FIG. 7I. A CMP etch may then have been performed using an etchant that has high selectivity for the material of dielectric layer 708 over the material of substrate 702. This would cause substrate 702 to act as an etch stop for the CMP. Contact point 718 may then have been formed by using similar masking and etching processes as were described above as forming magnetocaloric switches 710 and 712 and magnetocaloric heat sink 714.

FIGS. 7K and 7L depict two views of a sixth stage of forming cooling system 700. In this sixth stage, heat-producing device 720 has been placed upon contact 716. Further, dielectric layer 708 has been removed, which may beneficially increase thermal insulation of the heat energy produced by heat-producing device 720. In other words, removing dielectric layer 708 may help to prevent the heat energy that spreads from heat-producing device 720 to contact 716 and magnetocaloric 710 from spreading further to microcoil 706A or substrate 702.

In this stage, the operation of cooling system 700 can be understood. Specifically, by activating microcoil 706B, the heat capacity of magnetocaloric heat sink 714 would be increased. Further by activating microcoil 706A, the thermal conductance of magnetocaloric switch 710 would be increased. Thus, heat produced by heat-producing device 720 could pass through magnetocaloric switch 710 and into magnetocaloric heat sink 714. By deactivating microcoil 706A, the thermal conductance of magnetocaloric switch 710 could be reduced. This would prevent heat that has spread from magnetocaloric heat sink 714 from returning back to heat-producing device 720 through magnetocaloric switch 710.

After heat is isolated in magnetocaloric heat sink 714 by deactivating microcoil 706A, activating microcoil 706C would expose magnetocaloric switch 712 to a magnetic field, increasing its thermal conductance. This would enable the spread of heat from magnetocaloric heat sink 714 to contact point 718, which could then spread to the remainder of the system heat sink. Further, by deactivating microcoil 706B, the heat capacity of magnetocaloric heat sink 714 could be significantly reduced, causing heat to tend to exit magnetocaloric heat sink 714. Because magnetocaloric switch 710 is in a condition of low thermal conductance and magnetocaloric switch 712 is in a condition of high thermal conductance, that heat would pass through magnetocaloric switch 712 into contact point 718.

Some embodiments of the present disclosure can take the form of a first cooling system. The first cooling system may comprise a magnetocaloric heat sink, a device magnetocaloric switch, and a heat-sink magnetocaloric switch. The device magnetocaloric switch connects a heat-producing device to the magnetocaloric heat sink, and the heat-sink magnetocaloric switch is connected to the system heat sink. In these embodiments, the cooling system may act as a steady-state cooling system that is able to utilize magnetocaloric adiabatic cooling without moving parts.

In some embodiments of the first cooling system, the heat-sink magnetocaloric switch directly connects the magnetocaloric heat sink to the system heat sink. In these embodiments, the heat-sink magnetocaloric switch can be used to enable or prevent thermal transfer between the magnetocaloric heat sink and the system heat sink.

In some embodiments of the first cooling system, the magnetocaloric heat sink, the device magnetocaloric switch, and the heat-sink magnetocaloric switch are composed of the same material. This may result in manufacturing efficiencies.

In some embodiments of the first cooling system, the magnetocaloric heat sink is composed of a different material than the device magnetocaloric switch and the heat-sink magnetocaloric switch. Such a cooling system may enable selection of materials for the magnetocaloric heat sink and magnetocaloric switches that are particularly effective for those component functions.

In some embodiments of the first cooling system, the heat sink is formed of a semimetal. In some such embodiments, that semimetal may be niobium phosphide. In these embodiments, the significant magnetocaloric properties of niobium phosphide may increase the effectiveness of the first cooling system.

In some embodiments of the first cooling system, the cooling system comprises an electromagnet that is located adjacent to the magnetocaloric heat sink. This may enable control of the heat capacity and thermal conductance of the magnetocaloric heat sink. In some of these embodiments, the electromagnet may take the form of a solenoid. Such a solenoid could emit a strong magnetic field. In some embodiments, the electromagnet may take the form of a flat patterned coil. Such a coil may be scaled for extremely small cooling systems.

In some embodiments of the first cooling system, the cooling system comprises a first electromagnet that is located adjacent to the device magnetocaloric switch, a second electromagnet located adjacent to the magnetocaloric heat sink, and a third electromagnet located adjacent to the heat-sink magnetocaloric switch. Such embodiments may enable independent control of the first, second, and third electromagnets.

Some embodiments of the present disclosure may take the form of a second cooling system. The second cooling system comprises a magnetocaloric medium, a first set of electromagnets, and a second set of electromagnets. The magnetocaloric medium is connected to a heat-producing device and a system heat sink. The first set of electromagnets is located adjacent to a first region of the magnetocaloric medium. The first region is adjacent to the heat-producing device. The second set of electromagnets is located adjacent to a second region of the magnetocaloric medium. The second region is adjacent to the system heat sink. The second cooling system may enable independent control of the first and second sets of electromagnets, enabling the magnetocaloric medium to act as a heat pump.

In some embodiments of the second cooling system, the second cooling system comprises a third set of electromagnets located adjacent to a third region of the magnetocaloric medium. The third region partially overlaps the first region. This may enable precise heat transfer between the first region and the third region.

In some embodiments of the second cooling system, the first set of electromagnets comprises a first electromagnet and a second electromagnet and wherein the third set of electromagnets comprises the second electromagnet and a third electromagnet. This may further enable precise heat transfer between the first region and the third region.

In some embodiments of the second cooling system, the first set of electromagnets comprises a first electromagnet and a second electromagnet. The first electromagnet is located adjacent to a first section of the magnetocaloric medium. The second electromagnet is located adjacent to a second section of the magnetocaloric medium.

In some embodiments of the second cooling system, the electromagnets within the first set of electromagnets take the form of a set of patterned wires. This may enable efficient manufacturing of the first set of electromagnets.

In some embodiments of the second cooling system, the second cooling system comprises a thermally insulative layer between the magnetocaloric medium and the heat-producing device. This may discourage heat energy from transferring from the magnetocaloric medium to the heat-producing device.

Some embodiments of the present disclosure may take the form of a third cooling system. The third cooling system comprises a system heat sink and a first magnetocaloric thermal transport medium. The first magnetocaloric thermal transport medium is connected to the system heat sink. The first magnetocaloric thermal transport medium comprises a semimetal. This may enable a significant magnetocaloric effect in the first magnetocaloric thermal transport medium, increasing the effectiveness of the third cooling system in a solid-state design.

In some embodiments of the third cooling system, the first magnetocaloric thermal transport medium take the form of an intermediate magnetocaloric heat sink.

In some embodiments of the third cooling system, the third cooling system further comprises a first set of electromagnets adjacent to a first region of the first magnetocaloric thermal transport medium and a second set of electromagnets adjacent to a second region of the first magnetocaloric thermal transport medium. This may enable the first magnetocaloric thermal transport medium to act as a heat pump.

In some embodiments of the third cooling system, the semimetal is niobium phosphide. This may further enable a significant magnetocaloric effect in the first magnetocaloric thermal transport medium, increasing the effectiveness of the third cooling system in a solid-state design.

In some embodiments of the third cooling system, the third cooling system further comprises a second magnetocaloric medium. The second magnetocaloric medium comprises tantalum arsenide. This may enable selection of materials for the first and second magnetocaloric media that are particularly effective for those component functions.

Some embodiments of the present disclosure may take the form of a method of cooling a heat-producing device. The method may comprise activating a first set of electromagnets that are adjacent to a magnetocaloric medium. The activating the first set of electromagnets divides the magnetocaloric medium into an activated region and an inactivated region. This may, at least in part, enable the magnetocaloric medium to act as a heat pump.

In some embodiments of the method, the method further comprises deactivating the first set of electromagnets. The method further comprises activating a second set of electromagnets. The activating the second set of electromagnets results in a second activated region in the magnetocaloric medium. This may further enable the magnetocaloric medium to act as a heat pump.

In some embodiments of the method, the activated region has a higher specific heat capacity than the inactivated region. This may further enable the magnetocaloric medium to act as a heat pump.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A cooling system comprising:
a magnetocaloric heat sink;
a device magnetocaloric switch that connects a heat-producing device to the magnetocaloric heat sink;
a heat-sink magnetocaloric switch that is connected to a system heat sink.

2. The cooling system of claim 1, wherein the heat-sink magnetocaloric switch directly connects the magnetocaloric heat sink to the system heat sink.

3. The cooling system of claim 1, wherein the magnetocaloric heat sink, the device magnetocaloric switch, and the heat-sink magnetocaloric switch are composed of the same material.

4. The cooling system of claim 1, wherein the magnetocaloric heat sink is composed of a different material than the device magnetocaloric switch and the heat-sink magnetocaloric switch.

5. The cooling system of claim 1, wherein the heat sink is a semimetal.

6. The cooling system of claim 6, wherein the semimetal is niobium phosphide.

7. The cooling system of claim 1, further comprising an electromagnet located adjacent to the magnetocaloric heat sink.

8. The cooling system of claim 7, wherein the electromagnet takes the form of a solenoid.

9. The cooling system of claim 7, wherein the electromagnet takes the form of a flat patterned coil.

10. The cooling system of claim 1, further comprising:
a first electromagnet located adjacent to the device magnetocaloric switch;
a second electromagnet located adjacent to the magnetocaloric heat sink; and
a third electromagnet located adjacent to the heat-sink magnetocaloric switch.

11. A cooling system comprising:
a magnetocaloric medium connected to a heat-producing device and a system heat sink;
a first set of electromagnets located adjacent to a first region of the magnetocaloric medium, wherein the first region is adjacent to the heat-producing device; and
a second set of electromagnets located adjacent to a second region of the magnetocaloric medium, wherein the second region is adjacent to the system heat sink.

12. The cooling system of claim 11, further comprising a third set of electromagnets located adjacent to a third region of the magnetocaloric medium, wherein the third region partially overlaps the first region.

13. The cooling system of claim 12, wherein the first set of electromagnets comprises a first electromagnet and second electromagnet and wherein the third set of electromagnets comprises the second electromagnet and a third electromagnet.

14. The cooling system of claim 11, wherein the first set of electromagnets comprises a first electromagnet and a second electromagnet and wherein the first electromagnet is located adjacent to a first section of the magnetocaloric medium and wherein the second electromagnet is located adjacent to a second section of the magnetocaloric medium.

15. The cooling system of claim 11, wherein the electromagnets within the first set of electromagnets take the form of a set of patterned wires.

16. The cooling system of claim 11, further comprising a thermally insulative layer between the magnetocaloric medium and the heat-producing device.

17. A cooling system comprising:
a system heat sink;
a first magnetocaloric thermal transport medium connected to the system heat sink, wherein the first magnetocaloric thermal transport medium comprises a semimetal.

18. The cooling system of claim 17, wherein the first magnetocaloric thermal transport medium takes the form of an intermediate magnetocaloric heat sink.

19. The cooling system of claim 17, further comprising:
a first set of electromagnets adjacent to a first region of the first magnetocaloric thermal transport medium; and
a second set of electromagnets adjacent to a second region of the first magnetocaloric thermal transport medium.

20. The cooling system of claim 17, wherein the semimetal is niobium phosphide.

21. The cooling system of claim 20, further comprising a second magnetocaloric thermal transport medium, wherein the second magnetocaloric thermal transport medium comprises tantalum arsenide.

22. A method of cooling a heat-producing device, the method comprising:
activating a first set of electromagnets that are adjacent to a magnetocaloric medium, wherein activating the first set of electromagnets divides the magnetocaloric medium into an activated region and an inactivated region.

23. The method of 22, further comprising:
deactivating the first set of electromagnets; and
activating a second set of electromagnets, wherein activating the second set of electromagnets results in a second activated region in the magnetocaloric medium.

24. The method of claim 22, wherein the activated region has a higher specific heat capacity than the inactivated region.
